(19) United States
(12) Patent Application Publication
(10) Pub. No.: US 2020/0295286 A1
(43) Pub. Date: Sep. 17, 2020

(54) SEMI-TRANSPARENT AND MONOCHROMATIC ORGANIC PHOTOVOLTAIC DEVICES

(71) Applicant: The Regents of the University of Michigan, Ann Arbor, MI (US)

(72) Inventors: Stephen R. Forrest, Ann Arbor, MI (US); Lingjie J. Guo, Ann Arbor, MI (US); Yongxi Li, Ann Arbor, MI (US); Chengang Ji, Ann Arbor, MI (US)

(21) Appl. No.: 16/803,033

(22) Filed: Feb. 27, 2020

Related U.S. Application Data
(60) Provisional application No. 62/817,237, filed on Mar. 12, 2019.

(51) Int. Cl. H01L 51/44; H01L 51/42; H01L 51/00

(52) U.S. Cl. CPC H01L 51/447; H01L 51/441; H01L 51/0074; H01L 51/0072; H01L 51/4233

(57) ABSTRACT

An organic photovoltaic cell comprises a first electrode, a second electrode, an active layer comprising at least one donor material and at least one acceptor material, positioned between the first electrode and the second electrode, an outcoupling layer positioned on a surface of the first electrode such that the first electrode is positioned between the outcoupling layer and the active layer, and an anti-reflective coating positioned over a surface of the second electrode such that the second electrode is positioned between the anti-reflective coating and the active layer, wherein the organic photovoltaic cell is at least semi-transparent to at least one wavelength range. A method of fabricating an organic device is also described.

### CROSS-REFERENCE TO RELATED APPLICATIONS

This application claims priority to U.S. Provisional Application Ser. No. 62/817,237 filed on Mar. 12, 2019, incorporated herein by reference in its entirety.

### STATEMENT REGARDING FEDERALLY SPONSORED RESEARCH OR DEVELOPMENT

This invention was made with government support under DE-EE0006708 awarded by the Department of Energy. The government has certain rights in the invention.

### TECHNICAL FIELD

The present disclosure generally relates to electrically active, optically active, solar, and semiconductor devices, and in particular, to semi-transparent or monochromatic organic photovoltaic cells.

### BACKGROUND

Moving global energy consumption away from fossil fuels toward renewable sources is a promising way to decrease the rate of climate change. Among the many renewable energy sources available, solar energy is delivering on its promise of over 60 years as a low cost, clean, and essentially infinite supply of energy. However, the current installed area of photovoltaic (PV) technologies only provides approximately 2% of the worldwide energy demand. One obstacle for further growth of the solar energy market and the spread of its technologies is the cost and rate of installation of solar panels. The development of building-integrated PV (BIPV) that integrates transparent solar cells into or onto window panes and building facades provides an emerging opportunity for installation of solar cells in new locales that have yet to be fully exploited.

Semitransparent silicon solar cells on glass have been demonstrated to provide partial shading. However, broad optical absorption spectra of inorganic solar cells such as silicon limit their potential utility in BIPV applications. In contrast, organic semi-transparent photovoltaics (ST-OPVs) provide an attractive alternative due to their narrow band excitonic absorption spectra that may allow for visible light transmission and selective ultraviolet (UV)/near-infrared (NIR) absorption by the choice of molecular structure. Using such an approach, both high power conversion efficiency (PCE) and visible transmittance may be simultaneously achieved. Moreover, mechanical flexibility, pleasant appearance and light weight enhances their potential utility for BIPV applications.

Unlike opaque photovoltaics, semi-transparent photovoltaics may be considered as an effective solution for balancing energy generation with visual comfort. Moreover, the light utilization efficiency (LUE) provides a useful a figure of merit of ST-OPV performance. Light utilization efficiency (LUE) may refer to the product of power conversion efficiency (PCE) and average photopic transmittance (APT).

Recently, increasing attention has been dedicated to the development of low energy gap, NIR-absorbing organic materials to improve the performance of ST-OPVs. However, most systems still exhibit low LUE as result of trade-off between the PCE and APT.

As such, there remains a need to develop OPV cells, devices, and systems with improved power efficiency, average photopic transmittance, and/or light utilization efficiency.

### SUMMARY

Organic photovoltaic cells (OPVs) and their compositions are described herein. In one or more embodiments, the OPV or solar cell includes a first electrode; a second electrode; an active layer positioned between the first electrode and the second electrode; and an outcoupling (OC) layer that coats a surface of the first electrode such that the first electrode is positioned between the outcoupling layer and the active layer. The outcoupling layer is configured to enhance visible light transmission and/or near infrared light reflection through the OPV cell. In certain examples, variations in the thickness of one or more of the sublayers within the outcoupling layer may be advantageous in providing an OPV cell with a monochromatic transparency.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one aspect, an organic photovoltaic cell comprises a first electrode, a second electrode, an active layer comprising at least one donor material and at least one acceptor material, positioned between the first electrode and the second electrode, an outcoupling layer positioned on a surface of the first electrode such that the first electrode is positioned between the outcoupling layer and the active layer, and an anti-reflective coating positioned over a surface of the second electrode such that the second electrode is positioned between the anti-reflective coating and the active layer, wherein the organic photovoltaic cell is at least semi-transparent to at least one wavelength range.

In one embodiment, the outcoupling layer is configured to reflect at least a portion of light in a second wavelength range. In one embodiment, the second wavelength range comprises near-infrared light. In one embodiment, the anti-reflective coating is positioned on the surface of the second electrode. In one embodiment, the organic photovoltaic cell further comprises a substrate positioned between the second electrode and the anti-reflective coating. In one embodiment, the second electrode comprises indium tin oxide. In one embodiment, the first electrode comprises two metals. In one embodiment, the two metals are selected from the group consisting of Ag, Au, Pd, Pt, Ti, V, Zn, Sn, Al, Co, Ni, Cu, and Cr. In one embodiment, the two metals are Cu and Ag.

In one embodiment, the first electrode has a thickness of less than 15 nm. In one embodiment, the first electrode thickness is less than 10 nm. In one embodiment, the first electrode thickness is about 6 nm. In one embodiment, the outcoupling layer comprises a first sublayer comprising a metal compound, and a second sublayer comprising a carbazole derivative. In one embodiment, the metal compound is magnesium fluoride. In one embodiment, the carbazole derivative is 4,4′-Bis(N-carbazolyl)-1,1′-biphenyl. In one embodiment, the outcoupling layer has a thickness in a range of 100-300 nm.

In one embodiment, the wavelength range is selected from the group consisting of red light, blue light, and green light. In one embodiment, the at least one acceptor material comprises a non-fullerene acceptor. In one embodiment, the at least one acceptor material comprises two non-fullerene acceptors, and the at least one donor material comprises a polymer donor. In one embodiment, the non-fullerene acceptors comprise 4,4,10,10-tetrakis(4-hexylphenyl)-5,11-(2-ethylhexyloxy)-4,10-dihydro-dithienyl[1,2-b:4,5b′] benzodi-thiophene-2,8-diyl) bis(2-(3-oxo-2,3-dihydroinden-5,6-dichloro-1-ylidene) malononitrile and 4,4,10,10-tetrakis(4-hexylphenyl)-4,10-dihydrothieno [2″,3″:4′,5′] thieno[3′,2′:4,5]cyclopenta[1,2-b]thieno[2,3-d]thiophene-2,8-diyl)bis(2-(3-oxo-2,3-dihydroinden-5,6-difluoro-1-ylidene) malononitrile, and the polymer donor comprises poly[4,8-bis(5-(2-ethylhexyl)thiophen-2-yl)benzo[1,2-b;4,5-b′]dithiophene-2,6-diyl-alt-(4-(2-ethylhexyl)-3-fluorothieno[3,4-b]thiophene-)-2-carboxylate-2-6-diyl)].

In one embodiment, the organic photovoltaic cell further comprises a buffer layer positioned between the first electrode and the second electrode, the buffer layer comprising a material selected from the group consisting of MoO₃, V₂O₅, ZnO, or TiO₂. In one embodiment, the buffer layer is positioned between the active layer and the second electrode. In one embodiment, the organic photovoltaic cell further comprises an interfacial layer positioned between the buffer layer and the active layer. In one embodiment, the buffer layer comprises ZnO and the interfacial layer comprises a non-fullerene surfactant material.

In another aspect, an organic photovoltaic cell comprises an active layer comprising at least one donor material and at least one acceptor material, an electrode positioned over the active layer, comprising at least one metal material, and an outcoupling layer positioned over the electrode, the outcoupling layer configured to reflect at least a portion of near-infrared light, wherein the organic photovoltaic cell is configured to be at least semi-transparent to at least one wavelength range. In one embodiment, the organic photovoltaic cell further comprises a buffer layer positioned between the active layer and the electrode.

In one embodiment, the organic photovoltaic cell further comprises a distributed Bragg reflector positioned over the outcoupling layer. In one embodiment, the organic photovoltaic cell has an average transmittance in the visible range of at least 60%. In one embodiment, the average transmittance in the visible range is at least 70%. In one embodiment, the organic photovoltaic cell has a light utilization efficiency of at least 3%. In one embodiment, the organic photovoltaic cell has a power conversion efficiency of at least 5%.

In another aspect, a method of fabricating an organic device, comprises positioning a first electrode on a substrate, positioning an active layer over the first electrode, depositing a second electrode over the active layer, the second electrode being a thin film having a first metal deposited at a first deposition rate and a second metal different from the first metal deposited at a second deposition rate different from the first deposition rate, and positioning an outcoupling layer over the second electrode.

In one embodiment, the first and second metals are selected from the group consisting of Ag, Au, Pd, Pt, Ti, V, Zn, Sn, Al, Co, Ni, Cu, and Cr. In one embodiment, the first deposition rate is at least 50 times the second deposition rate. In one embodiment, the first metal is Ag and the second metal is Cu. In one embodiment, the first deposition rate is at least 1 nm/s and the second deposition rate is less than 0.02 nm/s. In one embodiment, the method further comprises positioning an anti-reflective coating beneath the first electrode. In one embodiment, the method further comprises depositing an interfacial layer between the first electrode and the active layer.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1A depicts a cross-sectional view of an exemplary semi-transparent organic photovoltaic (OPV) device.

FIG. 1B depicts a schematic of a semi-transparent OPV device with layer thicknesses and compositions. On the left, the molecular structural formulae of the interfacial layer, 4,4′-Bis(N-carbazolyl)-1,1′-biphenyl (“CBP”), donors (PCE-10) and acceptors (TT-FIC and BT-CIC) are depicted. On the right, detailed layer structures of the outcoupling layer, anti-reflection layer, and Bragg reflector are depicted.

FIG. 1C shows a detail view of the molecular structural formulae of the active layer from FIG. 1B.

FIGS. 2A-2D depict performance characteristics of semi-transparent solar cell performance having outcoupling and antireflection coatings. FIG. 2A depicts current density-voltage characteristics of the optimized semi-transparent cells with different cathode thickness. FIGS. 2B-2D depict measured quantum efficiencies and optical transmission and reflection characteristics of the semi-transparent cell with an 11 nm cathode (b), a 16 nm cathode (c), and a 21 nm cathode (d).

FIG. 3 depicts optical transmission characteristics of the semi-transparent cells with different cathodes. The Inset is a scanning electron microscope (SEM) image of a 8 nm pure Ag film, which shows an island surface morphology.

FIG. 4 depicts an ultraviolet-visible absorption spectra of a solar cell having an active layer including PCE-10, BT-CIC, and TT-FIC.

FIGS. 5A-5B depict electric field distributions within the semi-transparent solar cell based on the 21 nm CuAg cathode without the outcoupling layers (a) or with the outcoupling layers (b).

FIG. 5C depicts the calculated net phase shift of each layer of the outcoupling structures as a function of the wavelength.

FIG. 5D depicts simulated reflection and transmission spectra of the semi-transparent devices with and without outcoupling layers.

FIGS. 6A-6B depict electric field distributions within the semi-transparent solar cell based on the 11 nm CuAg cathode without the outcoupling layers (a) or with the outcoupling layers (b).

FIG. 6C depicts the calculated net phase shift of each layer of the outcoupling structures as a function of the wavelength.

FIG. 6D depicts simulated reflection and transmission spectra of the semi-transparent devices with and without outcoupling layers.

FIG. 7A depicts optical field distribution within the semi-transparent solar cell based on the 16 nm Cu—Ag cathode with the outcoupling layers.

FIG. 7B depicts simulated reflection and transmission spectra of the semi-transparent devices with and without outcoupling layers.

FIG. 7C depicts a calculated net phase shift of each layer of the outcoupling structures as a function of the wavelength.

FIG. 7D depicts the external quantum efficiency (EQE) spectra of semi-transparent solar cells with and without outcoupling layers.

FIG. 8A depicts the measured reflection ratio between glass substrates with and without anti-reflection coatings (ARC). Inset: ARC structure.

FIG. 8B depicts scanning electron microscope (SEM) 45° and side views of the SiO₂ film (porous) deposited on the Si substrate with 85° oblique angle.

FIGS. 9A and 9B depict current-density-voltage characteristics and external quantum efficiency (EQE) spectra of semi-transparent solar cells with different thickness of cathode.

FIG. 10A depicts a schematic of a semi-transparent device (21 nm CuAg) showing optimized layer thicknesses and compositions with both outcoupling (OC) and anti-reflection (AR) coatings.

FIGS. 10B-10D depict measured and simulated reflection and transmission spectra of the semi-transparent devices without OC and AR coatings (b), with only OC coatings (c), and with both OC and AR coatings (d).

FIG. 11A depicts a schematic of a semi-transparent device (16 nm CuAg) showing optimized layer thicknesses and compositions with both outcoupling (OC) and anti-reflection (AR) coatings.

FIGS. 11B-D depict measured and simulated reflection and transmission spectra of the semi-transparent devices without OC and AR coatings (b), with only OC coatings (c), and with both OC and AR coatings (d).

FIG. 12A depicts a schematic of a semi-transparent device (11 nm CuAg) showing optimized layer thicknesses and compositions with both outcoupling (OC) and anti-reflection (AR) coatings.

FIGS. 12B-D depict measured and simulated reflection and transmission spectra of the semi-transparent devices without OC and AR coatings (b), with only OC coatings (c), and with both OC and AR coatings (d).

FIG. 13 depicts a graph depicting light utilization efficiency (LUE) versus average photopic transmittance (APT) for various organic, inorganic, and perovskite solar cells.

FIG. 14 depicts measured transmission spectra of the semi-transparent devices (16 nm CuAg) with different illumination angles.

FIG. 15 depicts measured reflection spectrum of the distributed Bragg reflector.

FIGS. 16A-16B depict current-density-voltage characteristics and external quantum efficiency (EQE) spectra of semi-transparent solar cells (21 nm CuAg) with/without outcoupling and anti-reflection coatings.

FIGS. 17A-17B depict current-density-voltage characteristics and external quantum efficiency (EQE) spectra of semi-transparent solar cells (16 nm CuAg) with/without outcoupling and anti-reflection coatings.

FIGS. 18A-18B depict current-density-voltage characteristics and external quantum efficiency (EQE) spectra of semi-transparent solar cells (11 nm CuAg) with/without outcoupling and anti-reflection coatings.

FIG. 19A depicts a schematic of a multi-colored semi-transparent device with optimized layer thicknesses and compositions.

FIGS. 19B-19E depicts neutral and multi-colored semi-transparent solar cell structures and designs, with FIG. 19B depicting a photograph of an outdoor image, FIG. 19C depicting a photograph of the outdoor image through the blue cell, FIG. 19D depicting a photograph of the outdoor image through the green cell, and FIG. 19E depicting photograph of the outdoor image through the red cell.

FIGS. 20A-D depict performance characteristics of a multi-colored semi-transparent solar cell. FIG. 20A depicts CIE coordinates of the transmission spectra of devices with different colors using a AM1.5G solar simulated input spectrum. FIG. 20B depicts measured quantum efficiencies of the multi-colored semi-transparent cell. FIG. 20C depicts optical transmission and reflection characteristics of the multi-colored semi-transparent cells. FIG. 20D is a photograph of an outdoor image through the neutral-colored cell.

FIGS. 21A-C depict the optical field penetration into the solar cell based on the blue, green, and red device with the microcavity.

FIG. 22 depicts current-density-voltage characteristics of a multicolored semi-transparent cell.

FIG. 23A depicts CIE coordinates of the transmission spectra of devices with and without outcoupling layer using a AM1.5G solar simulated input spectrum.

FIG. 23B depicts simulated reflection and transmission spectra of the semi-transparent devices with and without outcoupling layers.

FIG. 23C depicts optical field distribution of the neutral-colored semitransparent solar cell.

FIG. 23D depicts the calculated net phase shift of each layer of the outcoupling structures as a function of the wavelength.

While the disclosed devices and systems are representative of embodiments in various forms, specific embodiments are illustrated in the drawings (and are hereafter described), with the understanding that the disclosure is intended to be illustrative and is not intended to limit the claim scope to the specific embodiments described and illustrated herein.

### DETAILED DESCRIPTION

It is to be understood that the figures and descriptions of the present invention have been simplified to illustrate elements that are relevant for a clear understanding of the present invention, while eliminating, for the purpose of clarity, many other elements found in related systems and methods. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

Various non-limiting examples of OPVs and compositions within various layers of an OPV are described in greater detail below.

### Definitions

As used herein, the terms “electrode” and “contact” may refer to a layer that provides a medium for delivering photo-generated current to an external circuit or providing a bias current or voltage to the device. That is, an electrode, or contact, provides the interface between the active regions of an organic photosensitive optoelectronic device and a wire, lead, trace or other means for transporting the charge carriers to or from the external circuit. Examples of electrodes include anodes and cathodes, which may be used in a photosensitive optoelectronic device.

As used herein, the term “transparent” may refer to a medium that permits the incident electromagnetic radiation in visible wavelengths to be transmitted through it. In some instances, the term “transparent” may be used with reference to one or more specific wavelengths or wavelength ranges of electromagnetic radiation, for example “transparent to green light” or “transparent to near infrared light.” As would be understood in the art, such use indicates that the medium permits the incident electromagnetic radiation in the indicated wavelength range to be transmitted through it.

As used herein, the term “semi-transparent” may refer to a medium that permits some, but less than 100% transmission of ambient electromagnetic radiation in one or more wavelength ranges. The electromagnetic radiation not transmitted may be reflected or absorbed by the medium or a component of the medium.

As used and depicted herein, a “layer” refers to a member or component of a photosensitive device whose primary dimension is X-Y, i.e., along its length and width. It should be understood that the term layer is not necessarily limited to single layers or sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the X-Y dimension may be disturbed or otherwise interrupted by other layer(s) or material(s).

As used herein, a “photoactive region” refers to a region of the device that absorbs electromagnetic radiation to generate excitons. Similarly, a layer is “photoactive” if it absorbs electromagnetic radiation to generate excitons. The excitons may dissociate into an electron and a hole in order to generate an electrical current.

As used herein, the terms “donor” and “acceptor” refer to the relative positions of the highest occupied molecular orbital (“HOMO”) and lowest unoccupied molecular orbital (“LUMO”) energy levels of two contacting but different organic materials. If the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

As used herein, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Because ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, the term “band gap” (E_{g}) of a polymer may refer to the energy difference between the HOMO and the LUMO. The band gap is typically reported in electronvolts (eV). The band gap may be measured from the UV-vis spectroscopy or cyclic voltammetry. A “low band gap” polymer may refer to a polymer with a band gap below 2 eV, e.g., the polymer absorbs light with wavelengths longer than 620 nm.

As used herein, the term “excitation binding energy” (E_{B}) may refer to the following formula: E_{B}=(M⁺+M⁻)−(M*+M), where M⁺ and M⁻ are the total energy of a positively and negatively charged molecule, respectively; M* and M are the molecular energy at the first singlet state (S₁) and ground state, respectively. Excitation binding energy of acceptor or donor molecules affects the energy offset needed for efficient exciton dissociation. In certain examples, the escape yield of a hole increases as the HOMO offset increases. A decrease of exciton binding energy E_{B} for the acceptor molecule leads to an increase of hole escape yield for the same HOMO offset between donor and acceptor molecules.

As used herein, “power conversion efficiency” (PCE) (η_{ρ}) may be expressed as:

$${η}_{ρ} = \frac{{V}_{OC} * F F * {J}_{SC}}{{P}_{O}}$$

wherein V_{OC} is the open circuit voltage, FF is the fill factor, J_{SC} is the short circuit current, and P_{O} is the input optical power.

As used herein, “spin coating” may refer to the process of solution depositing a layer or film of one or more materials (i.e., the coating materials) on a surface of an adjacent substrate or layer of material. The spin coating process may include applying a small amount of the coating material on the center of the substrate, which is either spinning at low speed or not spinning at all. The substrate is then rotated at high speed in order to spread the coating material by centrifugal force. Rotation is continued while the fluid spins off the edges of the substrate, until the desired thickness of the film is achieved. The applied solvent is usually volatile, and simultaneously evaporates. Therefore, the higher the angular speed of spinning, the thinner the film. The thickness of the film also depends on the viscosity and concentration of the solution and the solvent.

### Organic Photovoltaic Cells

As disclosed herein, various compositions or molecules may be provided within a solar cell or organic photovoltaic (OPV) cell. As supported by the Example section below, the various compositions or molecules for a semi-transparent OPV (ST-OPV) cell disclosed herein may be advantageous in providing one or more improvements over conventionally known ST-OPV cells. Such ST-OPVs may be integrated within a window pane to improve energy harvesting of solar irradiation. Reducing visible reflection and absorption are important to maximizing transmission and light utilization efficiency (LUE), which is the product of the power conversion efficiency and the average photonic transparency.

For example, the various OPV cell layers and devices disclosed herein may provide semi-transparent OPV cells (ST-OPVs) and devices having improved visible transmission and LUE over conventionally known ST-OPVs. Moreover, neutral and multi-colored ST-OPVs incorporating multilayer coatings may provide a wide variety of transmission colors (e.g., blue, green and red) with high efficiencies.

As disclosed herein, the improved semi-transparent OPV cells (ST-OPVs) and devices may include: an optical outcoupling (OC) layer, a first electrode, an active region or layer, a second electrode, and an anti-reflection coating (ARC) layer. Additional or fewer layers may be included as well.

The presence of the OC and/or ARC layer may enhance visible transmission within the ST-OPV cell while reflecting the near-infrared (NIR) light back into the cell. This may improve (e.g., double) the light utilization efficiency (LUE) when compared with a reference cell lacking the OC and ARC layers. In certain examples disclosed herein, the maximum LUE is at least 2.5%, at least 3%, at least 3.25%, at least 3.5%, at least 3.55%, or about 3.56% for an efficiency of at least 5.0%, at least 6.0%, at least 7.0%, or at least 8.0% at 1 sun, AM1.5G simulated emission is achievable.

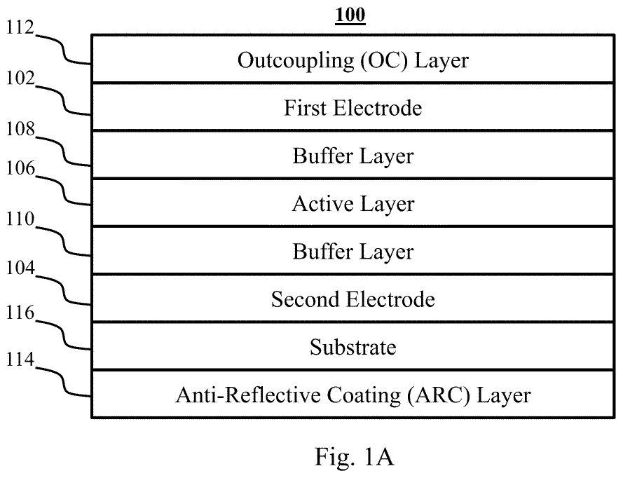

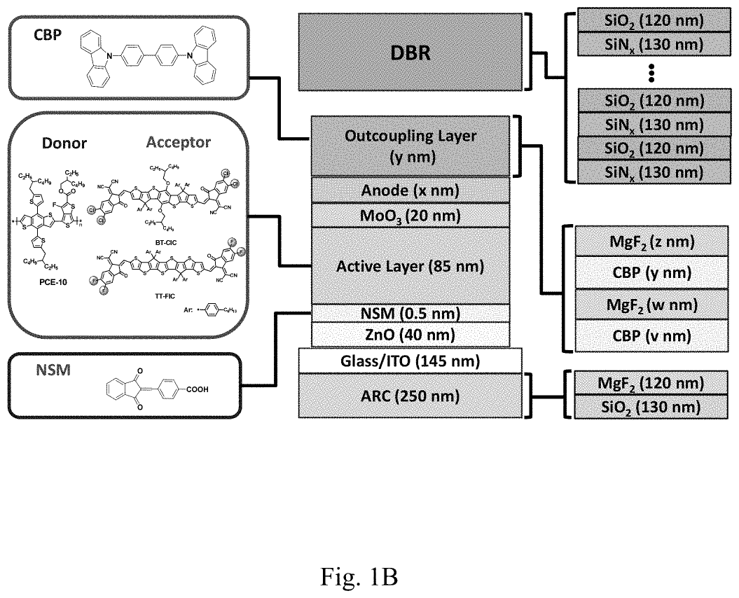

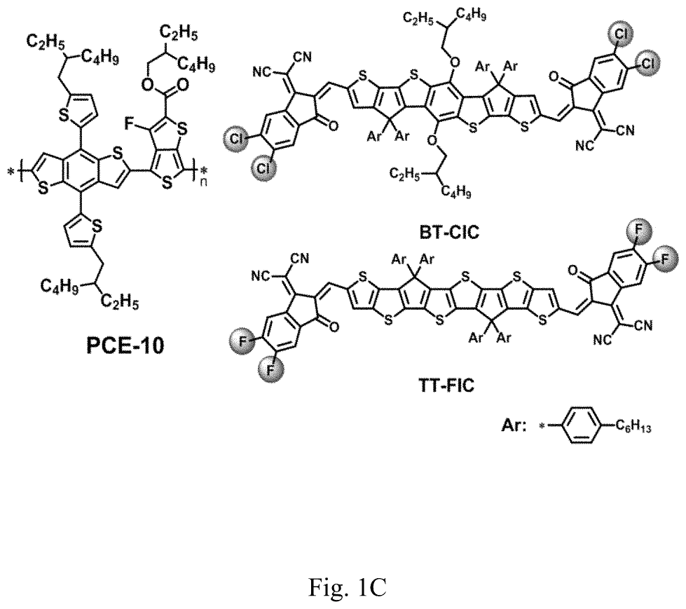

The various layers and their properties are disclosed in greater detail below with reference to FIGS. 1A and 1B.

### Organic Photovoltaic Cell Overview

FIG. 1A depicts an example of various layers of an OPV device. The OPV device may include an OPV cell 100 having a first electrode 102 and a second electrode 104 (e.g., an anode and a cathode) in superposed relation. The OPV cell may also include an active layer 106 positioned between the two electrodes 102, 104. In certain examples, at least one buffer layer 108 may be positioned between the first electrode 102 and the active layer 106. Additionally, or alternatively, at least one buffer layer 110 may be positioned between the active layer 106 and the second electrode 104.

In certain examples, an OC layer may be positioned adjacent to the first or second electrode 102, 104, such that the electrode is positioned between the OC layer and the active layer. In the depicted device 100, the OC layer 112 is positioned adjacent to the first electrode 102. An ARC layer may be positioned adjacent to the first or second electrode 102, 104, or adjacent to a substrate layer such that the electrode is positioned between the OC layer and the active layer. In the depicted device 100, the ARC layer is positioned adjacent to substrate 116, which itself is adjacent to second electrode 104. In some examples, both an OC layer and an ARC layer are present, wherein one of the OC layer or the ARC layer is positioned adjacent to the first electrode, and the other layer is positioned adjacent to the second electrode.

In certain examples, additional internal layers may be present within the OPV cell, such as an interfacial layer.

Non-limiting examples of the various compositions of the various layers of the OPVs are described herein.

### Electrodes

The first and second electrodes 102, 104 may be any transparent or semi-transparent material, such as graphene, carbon nanotubes, conductive polymers, metallic nanostructures, or ultrathin metal compositions. In certain embodiments, ultrathin metal films provide unique advantages of high conductivity, mechanical flexibility and simple preparation. The thickness of each electrode may be less than 100 nm, less than 50 nm, less than 10 nm, in a range of 0.1-1000 nm, 1-10 nm, 0.1-10 nm, 5-10 nm, 5-50 nm, 10-100 nm, or 50-500 nm, 100-1000 nm.

In certain examples, the first electrode 102 may be the anode and the second electrode 104 may be the cathode. While some examples disclosed herein refer to the first electrode 102 as the anode, the alternative may apply, wherein the first electrode is the cathode.

In some examples, the first electrode 102 and/or the second electrode 104 may include a conductive metal oxide, in some embodiments a transparent or semi-transparent conductive metal oxide, such as indium tin oxide (ITO), tin oxide (TiO), gallium indium tin oxide (GaITO), zinc oxide (ZnO), or zinc indium tin oxide (ZnITO). In other examples, the first electrode 102 and/or the second electrode 104 may include a thin metal layer, wherein the metal is selected from the group consisting of Ag, Au, Pd, Pt, Ti, V, Zn, Sn, Al, Co, Ni, Cu, Cr, or combinations thereof. In yet other examples, the first electrode 102 and/or the second electrode 104 may include a conductive polymer, in some embodiments a transparent or semi-transparent conductive polymer, such as polyanaline (PANI), or 3,4-polyethyl-enedioxythiophene:polystyrenesulfonate (PEDOT:PSS).

In some examples, first electrode 102 includes a first metal and a second metal, each having a volumetric concentration. In some embodiments, the volumetric concentration of the first metal in the electrode is roughly equal to the volumetric concentration of the second metal. In some embodiments, the volumetric concentration of the first metal is at least 2 times the volumetric concentration of the second metal. In other embodiments, the volumetric concentration of the first metal may be at least 5 times, at least 10 times, at least 20 times, at least 30 times, at least 40 times, at least 50 times, at least 75 times, or at least 100 times the volumetric concentration of the second metal. Volumetric concentration may be varied, for example, by varying the deposition rates of the two metals. For example, a volumetric concentration of 50:1 may be achieved in some embodiments by depositing the first metal at a first deposition rate at least 50 times the second deposition rate of the second metal. In one embodiment, the first deposition rate of the first metal is at least 0.2 nm/s, at least 0.5 nm/s, at least 0.7 nm/s, at least 0.8 nm/s, at least 0.9 nm/s, or at least 1 nm/s. The second deposition rate of the second metal may in some embodiments be at most at most 0.001 nm/s, at most 0.005 nm/s, at most 0.01 nm/s, at most 0.02 nm/s, at most 0.05 nm/s, at most 0.1 nm/s, or at most 0.5 nm/s.

In one particular example, the first electrode 102 includes an ultrathin metal film having a combination of copper and silver. The Cu—Ag film may include the addition of a small amount of Cu in Ag during co-sputtering. The deposition rates of Ag and Cu may be, for example, 1.109 nm/s and 0.019 nm/s, respectively, where Cu atoms act as nucleation centers for Ag atoms, thereby significantly modifying film growth dynamics by preventing Ag aggregating into islands. As a result, the continuous Cu—Ag films are may be achieved at thicknesses of only 6 nm, compared with 15 nm for a neat Ag layer.

In other examples, the first electrode 102 is an ultrathin metal film including silver. In some examples, the first electrode includes silver and at least one additional metal element such as copper, aluminum, nickel, titanium, gold, or a combination thereof. In certain examples, the weight percent amount of the additional metal element is less than 25 wt %, less than 20 wt %, less than 15 wt %, less than 10 wt %, less than 5 wt %, or less than 1 wt % of the first electrode metal film composition.

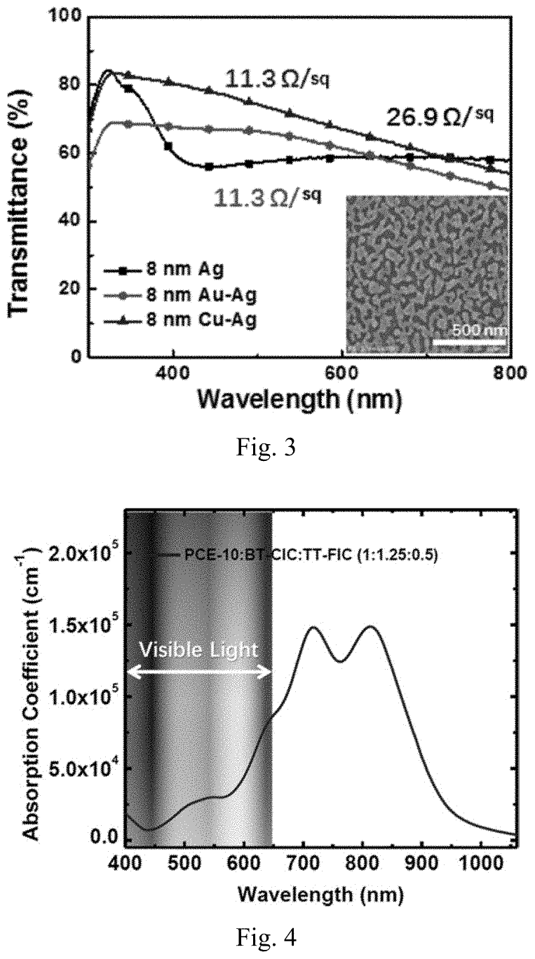

FIG. 3 shows the transmission spectra of three different ultrathin metal films (silver, silver with gold seed layer and copper silver composite). As a comparison, the Cu—Ag film shows the highest transmittance in the visible range with an average transmittance T_{avg}=75%, which is calculated from the simple arithmetic mean of the transmittances from 300 to 650 nm. While the transmittances for Ag and Ag—Au are relative lower with a T_{avg}=63% for Ag and T_{avg}=65% for Au—Ag. The strong visible absorption of Au atom is contributed to the low T_{avg} for Au—Ag film. However, the significantly drops of T_{avg} in pure Ag film is accompanied with the aggregation of Ag atom into islands on the surface of substrate. As shown in the inset of FIG. 3, the island-like morphology was found in the ultrathin Ag film with a root-mean-square roughness of RMS=6.25±0.3 nm. The isolated Ag grains introduce localized plasmon loss of the incident light, resulting in reduced transmittance. In contrast, both of the Cu—Ag and Au—Ag films exhibit RMS=0.70±0.04 nm for Cu—Ag and RMS=1.54±0.08 nm for Au—Ag film of comparable thickness. In addition, the sheet resistances of both Cu—Ag and Au—Ag films are 11.3±0.5 Ω/sq compared with 26.9±1.3 Ω/sq for Ag. In some embodiments, a thin metal film electrode for use with a disclosed device may have a sheet resistance of less than 20 Ω/sq, less than 15 Ω/sq, less than 13 Ω/sq, less than 12 Ω/sq, less than 11 Ω/sq, less than 10 Ω/sq, less than 8 Ω/sq, or less than 5 Ω/sq.

The second electrode 104 may include a conducting oxide, thin metal layer, or conducting polymer similar or different from the materials discussed above for the first electrode 102. In one particular example, the second electrode 104, which in some embodiments is a cathode, includes ITO.

### Active Layer

As noted above, at least one active region or layer 106 is present between the two electrodes 102, 104. The thickness of the active layer 106 is variable. In certain examples, the thickness of the active layer 106 may be between 0.1 nm and 1 μm, or between 0.1 nm and 500 nm, or between 1 nm and 200 nm, or between 1 nm and 100 nm, or less than 100 nm, or in a range of 10-100 nm, 50-100 nm, or 60-90 nm. In some embodiments the thickness of the active layer 106 is about 85 nm.

The active region or layer 106 positioned between the electrodes includes one or more compositions or molecules having an acceptor and a donor. In certain examples, the composition may be arranged as an acceptor-donor-acceptor (A-D-A′) or donor-acceptor-acceptor (d-a-a′). In other embodiments, more or fewer donors or more or fewer acceptors may be used.

In one particular example, the active layer includes two near-infrared (NIR) non-fullerene acceptors (e.g., TT-FIC, BT-CIC) and a polymer donor (PCE-10). The molecular structures of the donor and acceptors are shown in FIG. 1B, and in greater detail in FIG. 1C. Their nomenclatures are provided below. Both of BT-CIC and TT-FIC are acceptor-donor-acceptor structures, whose rigid planar backbones and electron-withdrawing end-capping fluorine and chlorine atoms improve the π-π interactions and reduce the energy gaps. Thin film ultraviolet-visible absorption spectrum of the ternary blend is shown in FIG. 4, showing strong absorption between wavelengths of λ=600 nm to 1000 nm while leaving a transparent window at the range of 400-600 nm.

Various additional examples of donor and acceptor compositions for the at least one active layer 106 are discussed in greater detail below.

### Donor Composition of Active Layer

In certain examples, the donor material or composition within the active layer or region 106 may be a polymer composition such as a low energy band gap polymer composition. For example, the donor composition may be a polymer having a band gap of less than 4 eV, less than 3 eV, less than 2.5 eV, less than 2 eV, or less than 1.5 eV.

One non-limiting example of a donor material or composition is poly[4,8-bis(5-(2-ethylhexyl)thiophen-2-yl)benzo[1,2-b:4,5-b′]dithiophene-co-3-fluorothieno[3,4-b]thio-phene-2-carboxylate, or a derivative thereof. Another example of a low band gap polymer donor is poly[4,8-bis(5-(2-ethylhexyl)thiophen-2-yl)benzo[1,2-b;4,5-b′]dithiophene-2,6-diyl-alt-(4-(2-ethylhexyl)-3-fluorothieno[3,4-b]thiophene+2-carboxylate-2-6-diyl)] (herein referred to as “PCE-10”), or a derivative thereof.

In another example, the donor is 2-[(7-{44N,N-Bis(4-methylphenyl)amino]phenyl}-2,1,3-benzothiadiazol-4-yl)methylene]propanedinitrile (herein referred to as “DTDCPB”), or a derivative thereof.

In another example, the donor includes 2-((7-(5-(dip-tolylamino)thiophen-21)benzo[c][1,2,5]thiadiazol-4-yl)methylene) malononitrile (herein referred to as “DTDCTB”).

Other non-limiting examples of low band gap polymer donors include the compounds depicted below in P1-P9, and their derivatives:

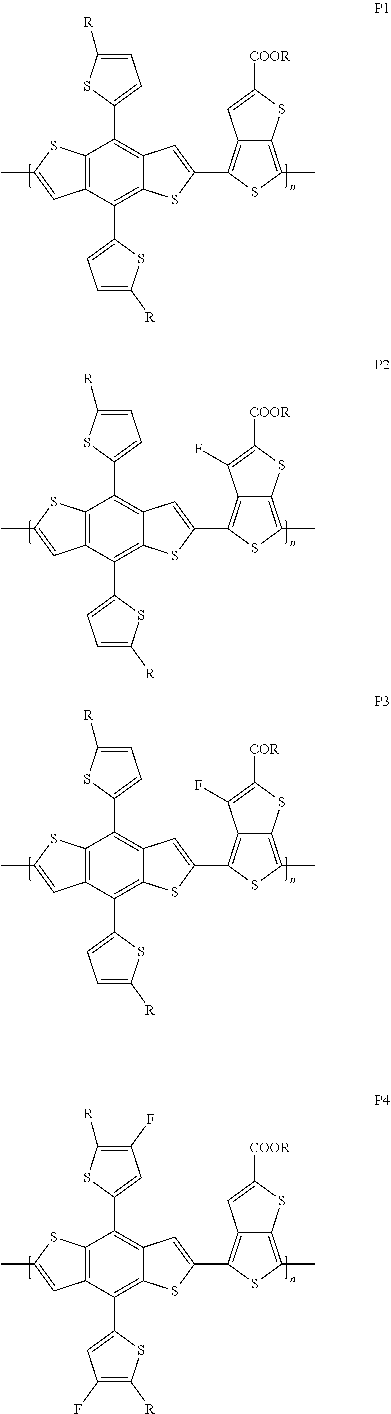

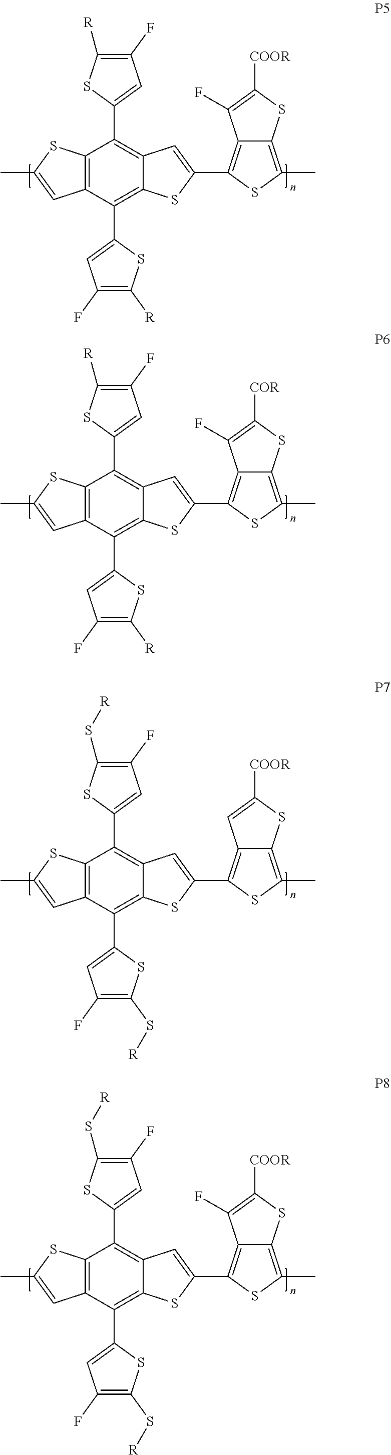

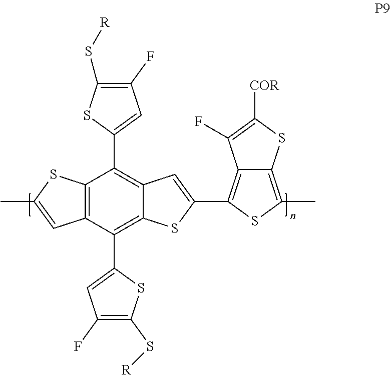

In the polymers depicted in P1-P9, n refers to the degree of polymerization. In some examples, n is within a range of 1-1000, 1-100, or 10-1000.

Additionally, R may represent a linear or branched saturated or unsaturated non-aromatic hydrocarbon, e.g., within the C₂-C₂₀ range. In certain examples, R represents a saturated hydrocarbon or alkyl group. Examples of linear or branched alkyl groups in the C₂-C₂₀ range include methyl, ethyl, n-propyl, isopropyl, isobutyl, n-butyl, sec-butyl, tert-butyl, isopentyl, n-pentyl, neopentyl, n-hexyl, and 2-ethylhexyl. In one particular example, R represents 2-ethylhexyl.

### Acceptor Composition

The acceptor in the active layer 106 may be a fullerene or non-fullerene acceptor molecule or composition. A fullerene molecule includes a hollow sphere, ellipsoid, or tube shape. The fullerene acceptor may be a spherical C₂₀, or C₂ₙ molecule, wherein n is an integer within a range of 12-100, for example. In certain examples, the fullerene acceptor is C₆₀ or C₇₀, or a derivative thereof.

Alternatively, the acceptor is a non-fullerene molecule. In such an example, the structure of the acceptor composition does not form a hollow sphere, ellipsoid, or tube. Non-limiting examples of a non-fullerene acceptor include:

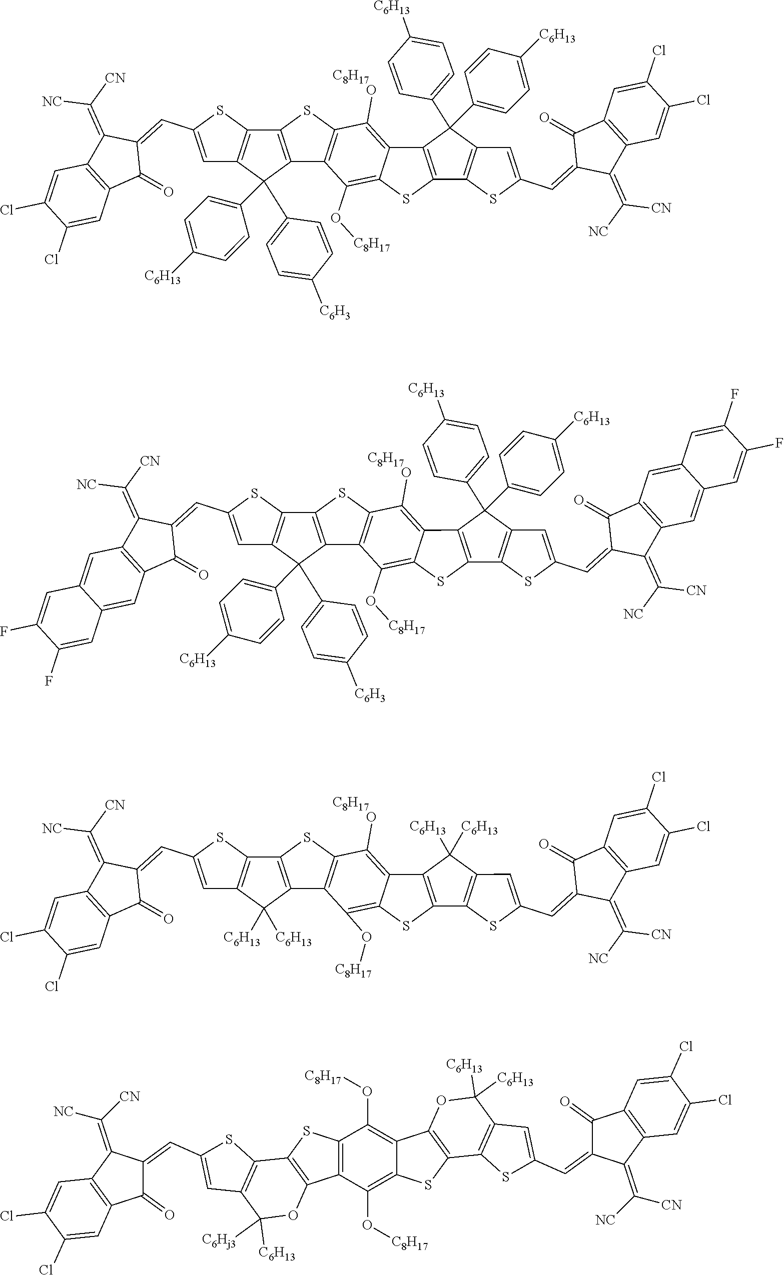

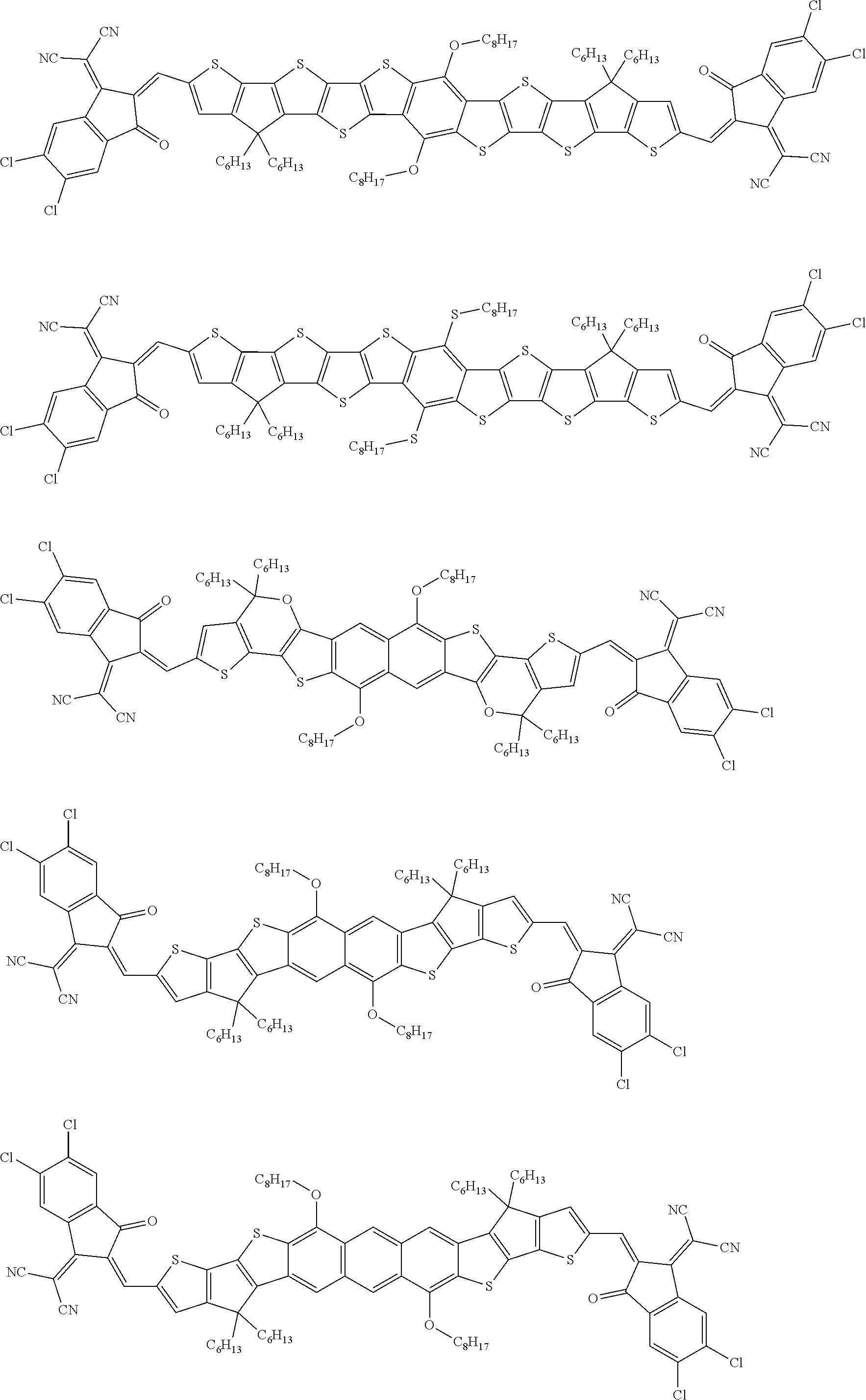

In one particular example, the non-fullerene acceptor is (4,4,10,10-tetrakis(4-hexylphenyl)-5,11-(2-ethylhexyloxy)-4,10-dihydro-dithienyl[1,2-b:4,5b′]benzodi-thiophene-2,8-diyl)bis(2-(3-oxo-2,3-dihydroinden-1-ylidene)malononitrile) (herein referred to as “BT-IC”). BT-IC has planar structure with a small torsion angle <1° and consequently, a high electron mobility. However, the absorption of BT-IC does not extend to wavelengths λ>850 nm. This leaves an unused part of the solar spectrum and a potential opening for further improvement in solar cell performance.

In another example, the non-fullerene acceptor is (4,4,10,10-tetrakis(4-hexylphenyl)-5,11-(2-ethylhexyloxy)-4,10-dihydro-dithienyl[1,2-b:4,5b′]benzodi-thiophene-2,8-diyl) bis(2-(3-oxo-2,3-dihydroinden-5,6-dichloro-1-ylidene) malononitrile (depicted in the structure below and in FIGS. 1B and 1C, herein referred to as “BT-CIC”). This structure provides a narrow absorption band confined to the near-infrared spectrum through the introduction of high electron affinity halogen atoms (e.g., chlorine atoms).

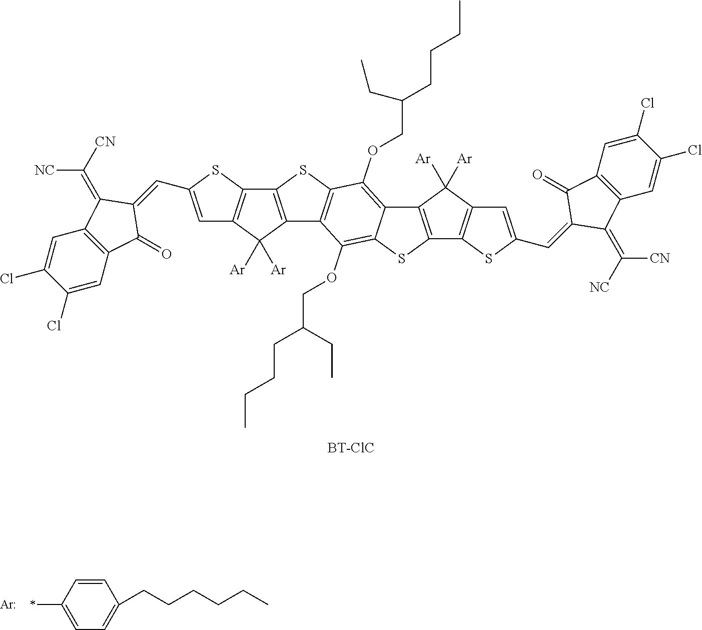

In this example, four chlorine atoms are positioned in the 5,6-positions of the 2-(3-oxo-2,3-dihydroinden-1-ylidene) malononitrile. The design is advantageous as it avoids significant issues of previously reported in chlorinated molecules with non-specific atomic site positioning (and hence property variability).

Such non-fullerene acceptor compositions disclosed herein provide certain improved characteristics over conventional acceptor compositions. For example, the NFAs disclosed herein may provide an increased electron density for the donor molecule; a reduced electron density for the acceptor molecule, and/or an increased conjugation length of the A-D-A′ molecule.

The electron-withdrawing halogen (e.g., Cl) atoms effectively lower the energy gap by enhancing the intramolecular charge transfer and delocalization of it-electrons into the unoccupied, atomic 3d orbitals. Moreover, the intermolecular interactions of Cl—S and Cl—Cl result in ordered molecular stacks in the donor-acceptor blend films.

In certain examples, the length of the non-fullerene acceptor may be at least 20 angstroms, 25 angstroms, 30 angstroms, 35 angstroms, 40 angstroms, 50 angstroms, or between 20-50 angstroms, 25-40 angstroms, or 25-35 angstroms.

### Buffer Layers

As noted above, the OPV may include one or more charge collecting/transporting buffer or electron blocking layers 108, 110 positioned between an electrode 102, 104 and the active region or layer 106. The buffer layer(s) is/are advantageous in protecting the adjacently positioned layers or compositions from adversely interacting with each other. Additionally, certain compositions within the buffer layer may be advantageous in further improving the power conversion efficiency (PCE) of the OPV or solar cell.

The first and second buffer layers 108, 110 may individually be a metal oxide. In certain examples, the first and second buffer layers 108, 110 may individually include one or more of MoO₃, V₂O₅, ZnO, or TiO₂. In some examples, the first buffer layer 108 has a similar composition as the second buffer layer 110. In other examples, the first and second buffer layers 108, 110 have different compositions.

The first and/or second buffer layers 108, 110 may include vacuum-deposited electron transporting compositions or molecules.

In some examples, the first and/or second buffer layers 108, 110 are selected from the group consisting of:

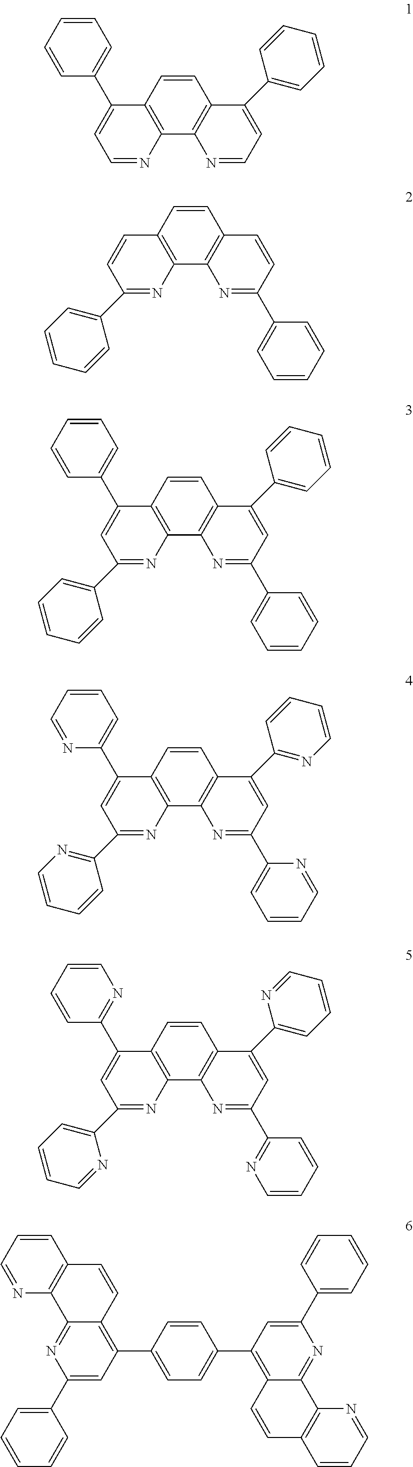

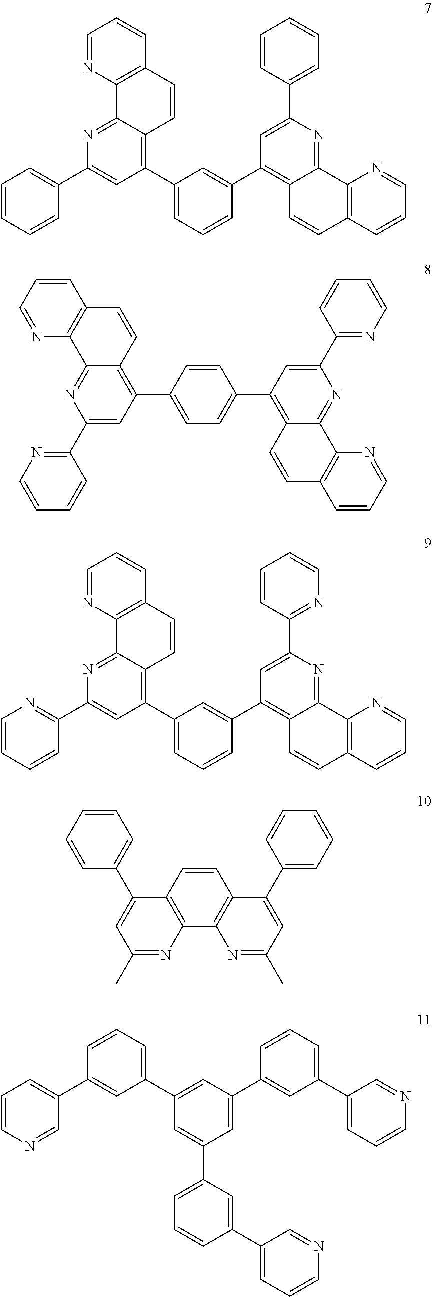

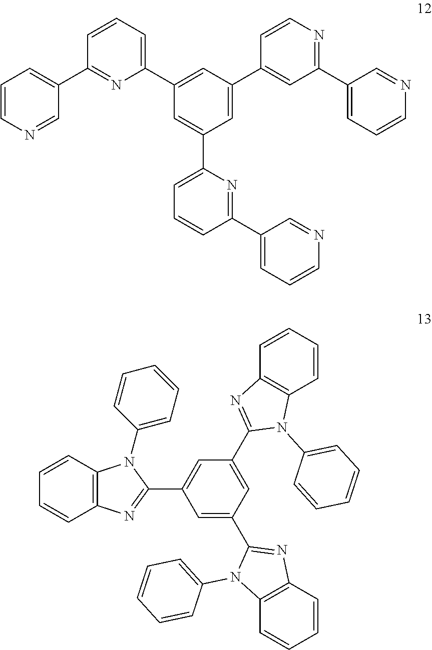

In certain examples, the first and/or second buffer layers 108, 110 include one or more of the following: 3,3′,5,5′-Tetra[(m-pyridyl)-phen-3-yl]biphenyl; 1,3-Bis[3,5-di(pyridin-3-yl)phenyl]benzene; 1,3,5-Tri(p-pyrid-3-yl-phenyl)benzene; or 2,4,6-Tris(3′-(pyridin-3-yl)biphenyl-3-yl)-1,3,5-triazine.

In one particular example, the first and/or second buffer layer 108, 110 includes 4,7-Diphenyl-1,10-phenanthroline (i.e., bathophenanthroline or “BPhen”) or a mixture of BPhen and a fullerene composition (e.g., C₆₀). In some examples, the mixed electron blockers or buffer layer may include a 1:1 volume ratio BPhen:C₆₀ (e.g., with BPhen adjacent to the electrode).

The thickness of each buffer layer 108, 110 may be 0.1 nm to 1 μm, 0.1 nm to 500 nm, 0.1 nm to 200 nm, 0.1 nm to 100 nm, 0.1 nm to 50 nm, 10 nm to 50 nm, 1 nm to 10 nm, 0.1 nm to 10 nm, or 10 nm to 100 nm.

### Outcoupling Layer

As noted above, the OPV may include an outcoupling (OC) layer 112 positioned adjacent to an electrode (e.g., the first electrode 102) such that the electrode is positioned between the outcoupling layer 112 and the active layer 106. The outcoupling layer 112 may provide an external coating to a surface of the OPV cell 100 (e.g., by coating the surface of the first electrode).

The outcoupling layer 112 may be advantageous in improving or enhancing transmission of visible light. The OC layer 112 may also be configured to reflect or recycle near-infrared (NIR) light for absorption within the active layer.

In certain examples, the OC layer 112 is configured to enhance transmission within a specific wavelength range of visible light (e.g., visible light within 400-500 nm wavelength, 500-600 nm wavelength, 600-700 nm wavelength, 400-600 nm wavelength, 380-750 nm wavelength, or 500-700 nm wavelength). In some examples, the OC layer 112 is configured to enhance transmission within a specific color spectrum of visible light (e.g., violet light within 380-450 nm wavelength, blue light within 450-495 nm wavelength, green light within 495-570 nm wavelength, yellow light within 570-590 nm wavelength, orange light within 590-620 nm wavelength, or red light within 620-750 nm wavelength).

The OC layer 112 may be a multi-layer composition having one or more alternating metal compound sublayers and carbazole derivative sublayers. A metal compound sublayer may include magnesium fluoride. A carbazole derivative sublayer may include 4,4′-Bis(N-carbazolyl)-1,1′-biphenyl (CBP). In one particular example, the OC layer 112 may include a plurality of sublayers (e.g., four sublayers), alternating between a carbazole derivative such as CBP (index of refraction, nCBP=1.90±0.03) and a metal compound sublayer such as MgF₂ (nMgF₂=1.38±0.01). The CBP/MgF₂ multi-layer outcoupling coating layer may deposited onto the electrode surface (see FIG. 1B).

The OC layer 112 may have an overall thickness in a range of 1 nm to 1 μm, 1 nm to 500 nm, 10 nm to 400 nm, 100 nm to 300 nm, 100 nm to 200 nm, or 200 nm to 300 nm.

In certain examples, each individual metal compound (e.g., magnesium fluoride) sublayer in the plurality of sublayers has a thickness in a range of 1-300 nm, 10-200 nm, 10-100 nm, 100-200 nm, 10-50 nm, 50-150 nm, or 100-150 nm. In certain examples, the OC layer has a plurality of metal compound sublayers, and a first metal compound sublayer has a thickness in a range of 10-100 nm, and a second metal compound sublayer has a thickness in a range of 50-150 nm. In various embodiments, individual metal compound sublayers within the OC layer may have about the same thickness as one another or one or more metal compound sublayers may have a thickness different from the others.

In certain examples, each individual carbazole derivative (e.g., CBP) sublayer in the plurality of sublayers has a thickness in a range of 0.1 nm-1 μm, 1-500 nm, 1-300 nm, 1-200 nm, 10-100 nm, 100-200 nm, 10-50 nm, or 50-100 nm. In certain examples, the OC layer has a plurality of carbazole derivative sublayers, and a first carbazole derivative sublayer has a thickness in a range of 10-50 nm, and a second carbazole derivative sublayer has a thickness in a range of 50-100 nm.

The various thicknesses and compositions within the sublayers of the OC layer are advantageous in providing resonances within the sublayers and enhancing visible light transmission through the ST-OPV within a specific wavelength range. Adjustments to the thicknesses of the overall OC layer as well as the individual sublayers (e.g., the magnesium fluoride and CBP sublayers) within the plurality of sublayers of the OC coating layer 112 may alter the transmission of visible light (or a portion of visible light). In certain examples, the thickness of the OC layer and various sublayers may be configured to provide the transmission of monochromatic light.

For example, as disclosed in the Examples below, red, green, and blue transparencies were generated when the CBP sublayer of the OC layer was 125 nm thick, 90 nm, and 60 nm, respectively.

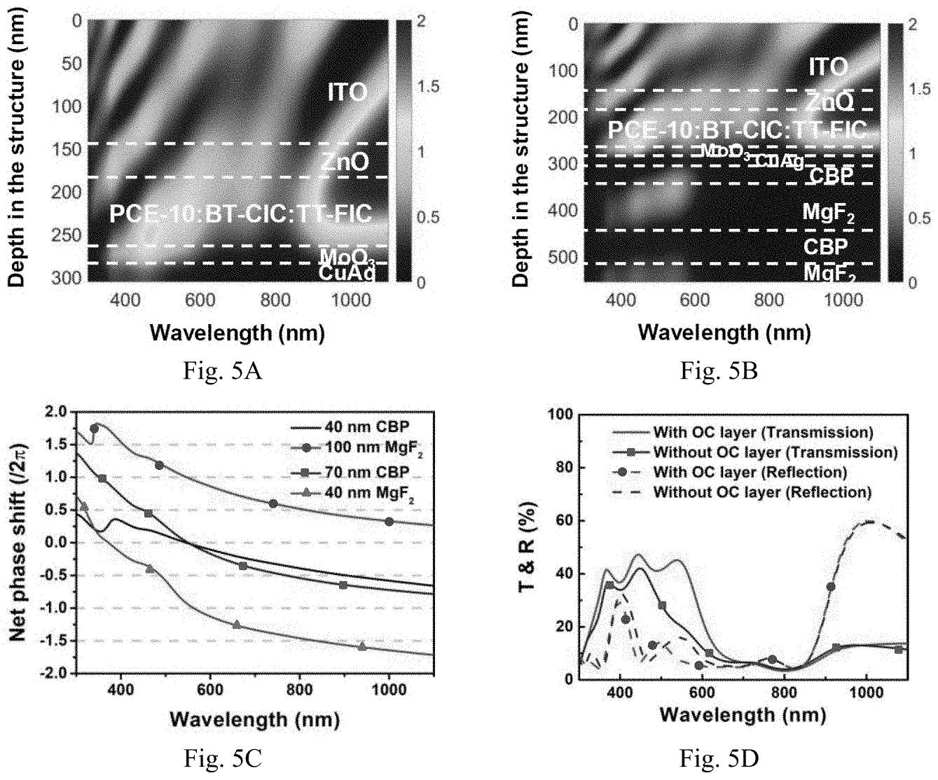

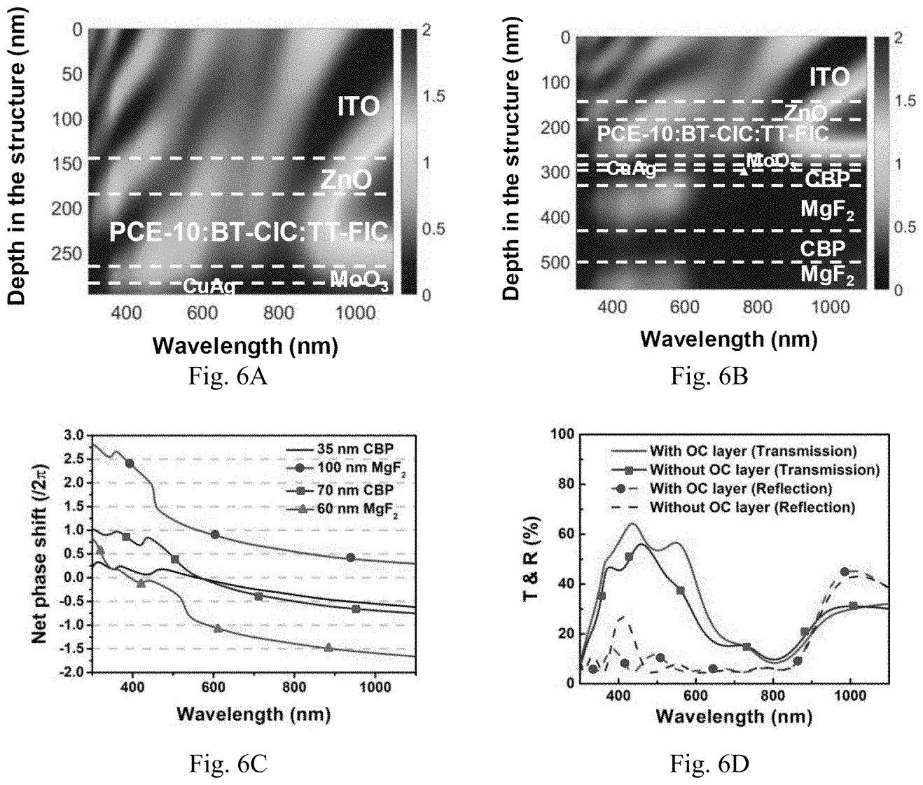

FIGS. 5A-5D and FIGS. 6A-6D illustrate examples of the multiple functions of the OC layers. FIG. 5A shows electric field distribution within a semi-transparent solar cell based on a 21 nm CuAg cathode without the outcoupling layers, while FIG. 5B shows the electric field distribution for a similar semi-transparent solar cell with the outcoupling layers. FIG. 5C shows the calculated net phase shift of each layer of the outcoupling structures as a function of the wavelength. FIG. 5D shows the simulated reflection and transmission spectra of the semi-transparent devices with and without outcoupling layers.

FIGS. 6A through 6D show the corresponding graphs of FIGS. 5A through 5D, but with a device based on an 11 nm CuAg cathode.

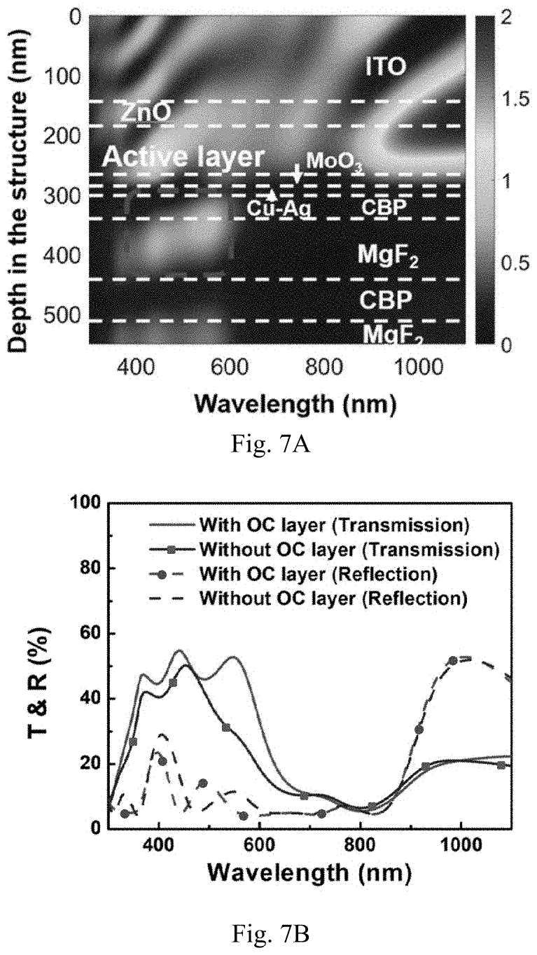

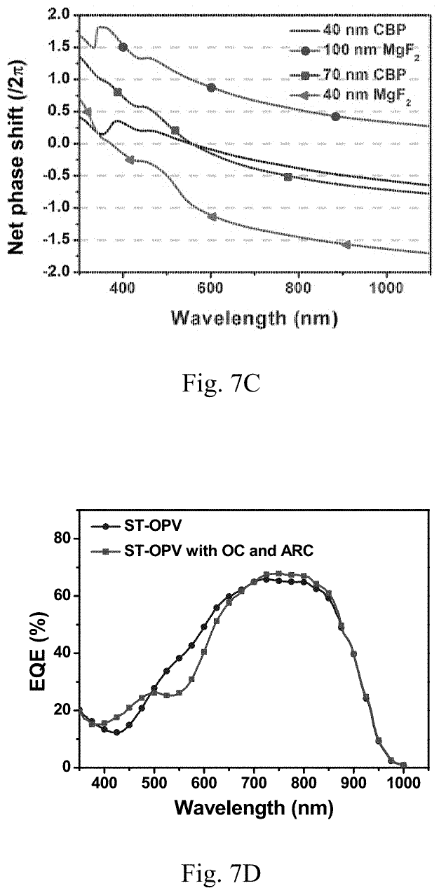

In one additional example, an ST-OPV with an x=16 nm thick Cu—Ag electrode is used. FIG. 7A provides the optical field intensity in the 16 nm Cu—Ag device with the OC layer versus wavelength. The OC layer induces enhanced transmission between 400 nm and 600 nm with a peak at 555 nm, which is consistent with the transmission spectra in FIG. 7B. The enhanced transparency results from resonances within the OC stacks. The phase shift analysis in FIG. 7C shows a transmission resonance phase shift near 555 nm inside each layer, i.e., the optical field has maxima at 554 nm in the 40 nm thick CBP, at 555 nm in 100 nm thick MgF₂, 557 nm in 70 nm thick CBP, and at 568 nm in 40 nm thick MgF₂. On the other hand, the reflection spectrum has a maximum at λ>600 nm within enhances NIR reflection for energy harvesting.

### Anti-Reflective Coating Layer

As noted above, the OPV may include an anti-reflective coating (ARC) layer 114 positioned adjacent to an electrode (e.g., the second electrode 104) such that the electrode is positioned between the ARC layer 114 and the active layer 106. In one particular example, the ARC layer 114 is positioned directly adjacent (on) a surface of the second electrode 104. In an alternative example, a substrate (e.g., glass) is positioned between the second electrode 104 and the ARC layer 114, such that the ARC layer 114 is positioned on a surface of the substrate (e.g., glass).

The ARC layer 114 may provide an external coating to one surface of the OPV cell 100 (e.g., the opposite surface from the outcoupling layer 112).

The ARC layer 114 may be configured to, in combination with the OC layer 112, improve or enhance transmission and reduce reflection within the visible light range and/or reflect or recycle near-infrared (NIR) light for absorption within the active layer. In some examples, the ARC layer 114 may be advantageous in improving the power conversion efficiency (PCE) of the solar cell.

The ARC layer 114 may include a plurality of sublayers, in some embodiments alternating sublayers of contrasting refractive index. The plurality of sublayers of the ARC may include a first sublayer comprising magnesium fluoride (MgF₂) and a second sublayer comprising silicon dioxide (SiO₂). In some examples, the ARC has a thickness in a range of 1-1000 nm, 10-500 nm, 100-500 nm, 100-700 nm, 100-300 nm, or 200-300 nm.

In one particular example, to reduce optical losses, the ARC layer 114 may include a bilayer of 120 nm MgF₂ (index of refraction, nMgF₂=1.38±0.01) and 130 nm low refractive index SiO₂ (nSiO₂=1.12±0.03 obtained via glancing-angle deposition, as discussed in greater detail in the Method section below). The bilayer may be deposited onto an external or distal surface of the glass substrate.

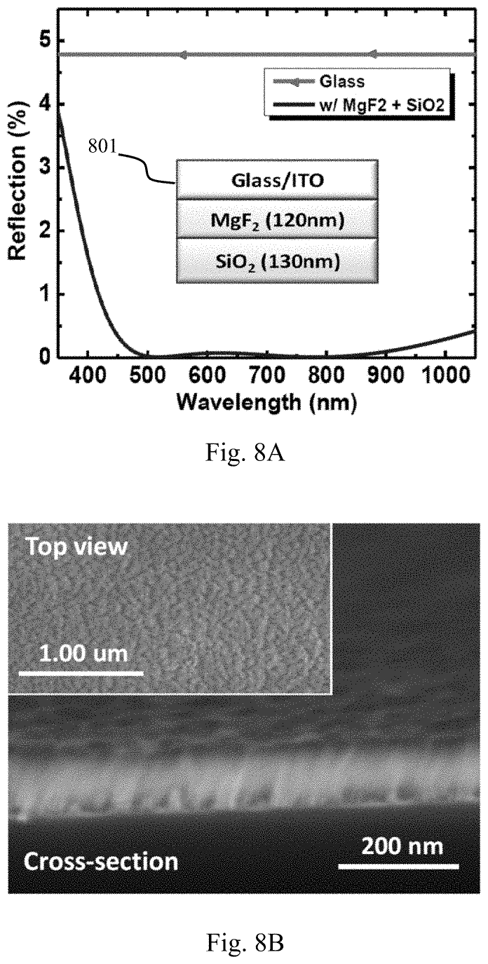

FIG. 8A shows the measured reflection ratio between the glass substrates with and without anti-reflection coatings (ARC). The inset 801 of FIG. 8A shows the structure of the ARC. FIG. 8B depicts the SEM top and cross-section views of the SiO₂ film deposited on the substrate with an 85° oblique angle.

### Additional Layers

As noted above, the OPV device may include additional internal layers. In one example, the OPV cell 100 may include an interfacial layer. The interfacial layer may be positioned between the active layer 106 and one of the buffer layers 108, 110. In one particular example, the interfacial layer is positioned between the active layer 106 and the buffer layer 110 which is adjacent to the second electrode 104.

Such a layer may be advantageous in suppressing charge trapping at defects on the adjacent buffer surface.

In certain examples, the interfacial layer may include a non-fullerene surfactant material (NSM). Nonlimiting examples of NSM components include one or more of the following:

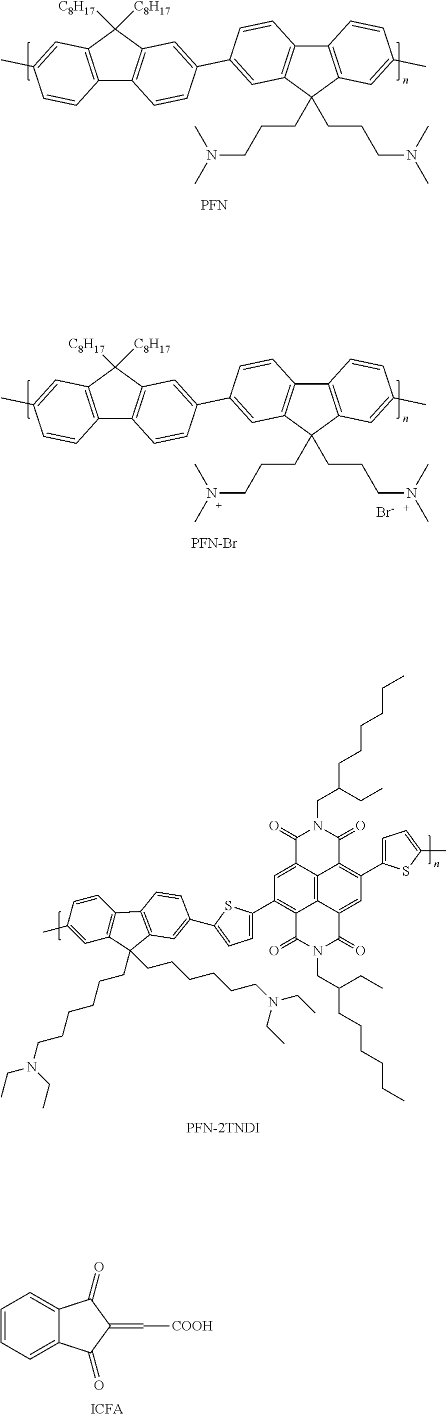

### Substrate

The OPV device may include a substrate positioned to support the OPV cell 100. In some embodiments, the substrate may be positioned adjacent to the first or second electrode. As depicted in FIGS. 1A and 1B, a substrate 116 may be positioned between the second electrode 104 and the ARC layer 114.

The substrate 116 may comprise any material configured to support the OPV cell. In certain examples, the substrate is a transparent material such as glass. In alternative examples, the substrate may be a semi-transparent material.

### OPV Performance Characteristics

In certain examples, the ST-OPV or solar cell may have certain improved performance properties. For example, the solar cells disclosed herein may include an improved light utilization efficiency (LUE), power conversion efficiency (PCE), and/or average photopic transmittance (APT).

Unlike conventional ST-OPVs, where the enhancement in LUE primarily originates from enhanced NIR light harvesting, the ST-OPVs disclosed herein may be achieved by reducing the visible reflection and improving transmission using an outcoupling (OC) coating layer, an anti-reflection (ARC) coating layer, or a combination thereof. Furthermore, the coatings may enhance the NIR reflectivity, resulting in an increase in absorption at long wavelengths, and hence a high external quantum efficiency.

In certain examples, an ST-OPV cell may have strong absorption characteristics within a visible/NIR wavelength range while having a transparent window within a separate visible wavelength range. For example, an ST-OPV cell may have a strong absorption in a wavelength range of 600-1000 nm, while having a transparent window in a wavelength range of 400-600 nm.

In certain examples, the ST-OPV cell may have a LUE that is twice that of a cell lacking the OC and ARC coatings. The photon management by an OC and ARC structure is advantageous to reduce the visible reflection, improve visible transmission, and improve NIR harvesting. This is advantageous in providing freedom in varying device architectures and the materials without changing the electrical characteristics of the device itself. In other words, the OC and ARC coatings may be applied to a variety of different OPV cells to improve the LUE. Therefore, both the PCE and APT can be independently optimized to deliver the highest performance.

In certain examples, the semi-transparent solar cell may have a LUE of at least 2.5%, at least 2.75%, at least 3.0%, at least 3.25%, or at least 3.5%. In some examples, the solar cells disclosed herein have a LUE in a range of 2.5-3.56%, 3-3.56%, 3.25-3.56%, or 3.5-3.56%.

In certain examples, the semi-transparent solar cell may have a PCE of at least 5%, at least 6%, at least 7%, at least 8%, or at least 9%. In some examples, the solar cells disclosed herein have a PCE in a range of 5-15%, 6-10%, or 8-9%.

In certain examples, the semi-transparent solar cell may have an APT of at least 20%, at least 30%, at least 40%, or at least 50%. In some examples, the solar cells disclosed herein have an APT in a range of 30-60% or 40-50%.

The solar cells disclosed herein may have an improved fill factor (FF). The FF may be at least 50%, at least 60%, at least 65%, at least 70%, at least 75%, at least 80%, in a range of 50-80%, in a range of 60-80%, in a range of 65-75%, or approximately 70%.

The solar cells disclosed herein may have a high short circuit current (J_{sc}). The J_{sc} may be in a range of 10-30 mA/cm², 10-20 mA/cm², or 14-19 mA/cm².

In certain examples, the transparency level of the solar cell may be adjusted by the thickness of one or more of the layers (e.g., the outcoupling layer thickness). By altering the thickness, the ST-OPVs disclosed herein may cover a wide color gamut (e.g., blue, green, or red). In one example, the ST-OPV has a PCE=8.9±0.3% and a peak transmittance of Tₚₑₐₖ=39.3±1.5% for a blue device. In another example, the ST-OPV has a PCE=8.7±0.2% and Tₚₑₐₖ=32.2±1.3% for a green device. In another example, the ST-OPV has a PCE=8.3±0.3% and Tₚₑₐₖ=22.3±0.7% for a red device. In another example, the ST-OPV has a PCE=5.8±0.2%, and APT=44.3±1.5% for a neutral colored device. This may be demonstrated with Commission Internationale d'Eclairage chromaticity coordinates, (CIE)=(0.337, 0.349) and a color rendering index (CRI)=87 when illuminated by a simulated, AM1.5G, solar spectrum.

### Experimental Examples

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the system and method of the present invention. The following working examples therefore, specifically point out the exemplary embodiments of the present invention, and are not to be construed as limiting in any way the remainder of the disclosure.

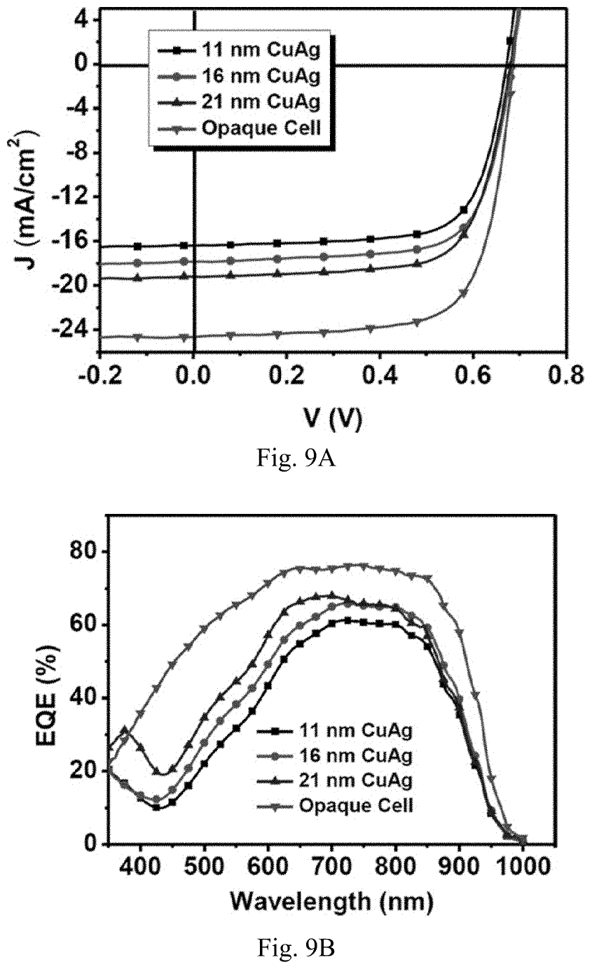

To systematically study the trade-off between transparency and efficiency, a comparative example opaque cell was prepared with the structure: ITO/ZnO (40 nm)/NSM (0.5 nm)/PCE-10:BT-CIC:TT-FIC (1:1.25:0.5, 85 nm)/MoO₃ (20 nm)/Ag (100 nm). The opaque cell attains short-circuit current of J_{SC}=23.3±0.4 mA/cm², open circuit voltage V_{OC}=0.68±0.01 V and fill factor FF=0.72±0.01, resulting in PCE=11.4±0.3%, which is comparable to that of an analogous conventional cell. The current-density-voltage (J-V) characteristics and external quantum efficiencies EQE spectra for the devices are shown in FIGS. 9A-B, with a summary of device performance in Table 1.

ST-OPVs with OC layers were fabricated with the device structures: ITO/ZnO (40 nm)/NSM (0.5 nm)/PCE-10:BT-CIC:TT-FIC (1:1.25:0.5, 85 nm)/MoO₃ (20 nm)/Cu—Ag (x nm)/CBP (v nm)/MgF₂ (w nm)/CBP (y nm)/MgF₂ (z nm). ZnO was used as an electron transporting layer, MoO₃ as the hole transporting layer. NSM is an interfacial material used to suppress charge trapping at defects on the ZnO surface, as discussed above.

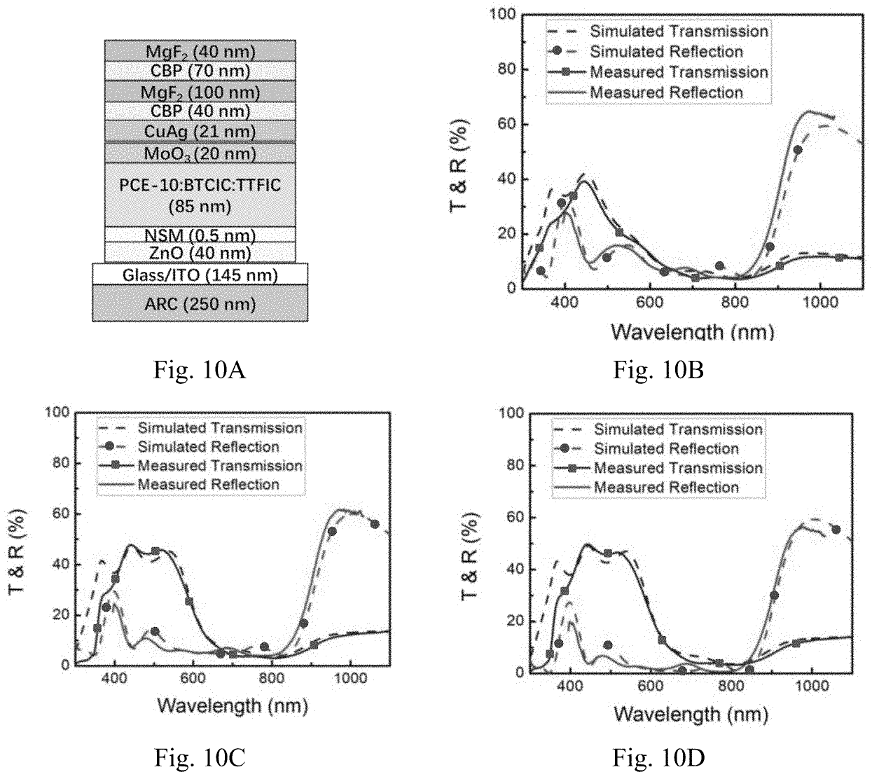

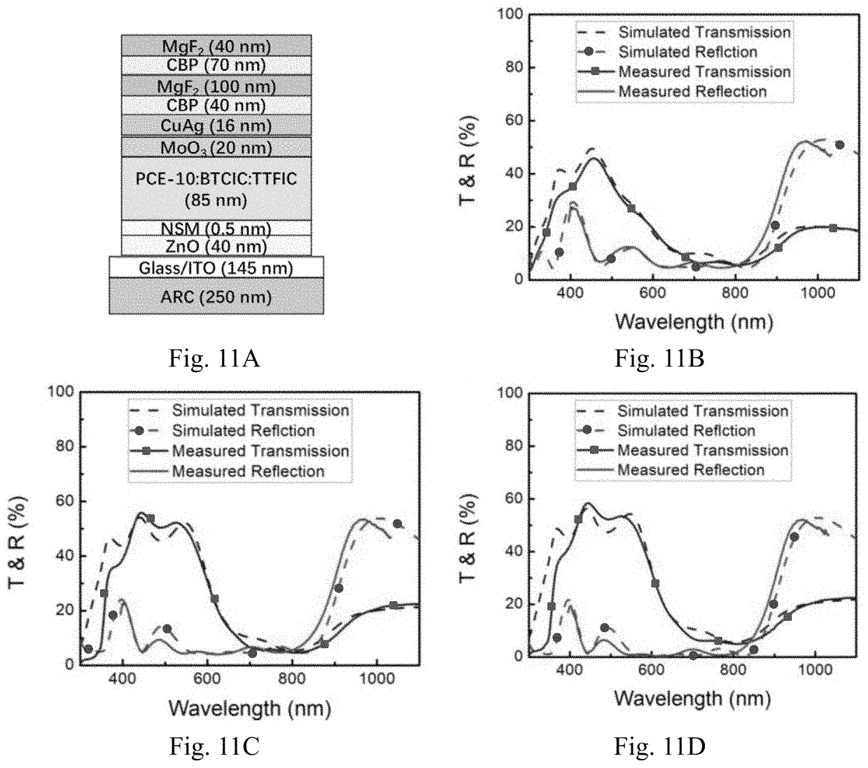

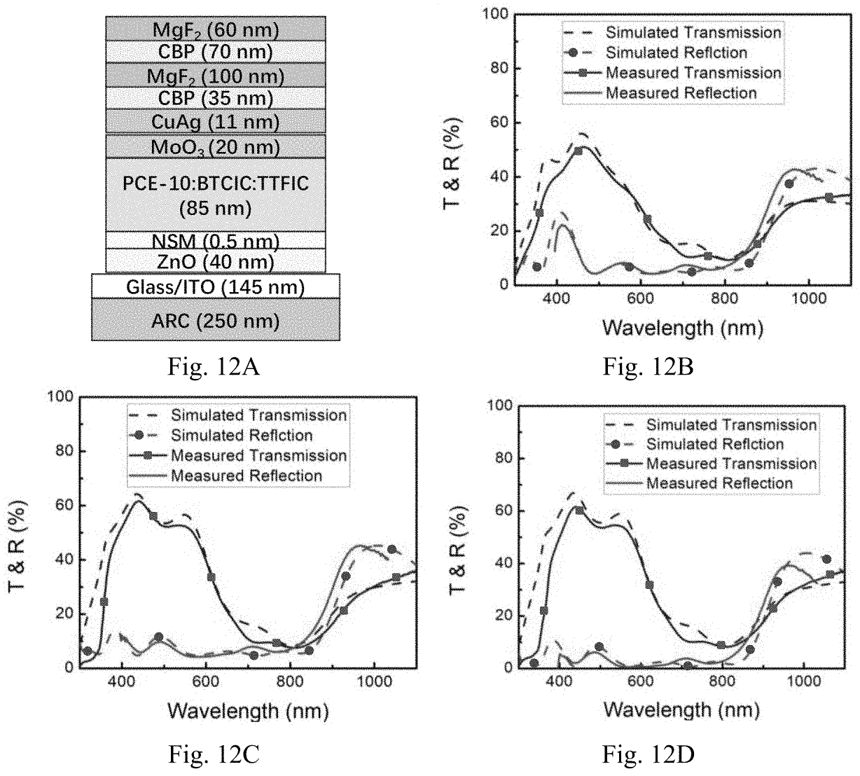

The ST-OPV with Cu—Ag thicknesses of x=21 nm, shows the APT increases from 17.8±0.5% to 34.1±1.2%, or nearly twice that of a cell without an OC coating. For x=16 and 11 nm, 61% and 35% improvement in APT are achieved, with APT=42.6±1.3% and 47.2±1.5%, respectively. This APT enhancement is due to both improved visible transmission and decreased visible reflection, in agreement with simulations. The device structures, transmission and reflection spectra are plotted in FIGS. 10A-D, FIGS. 11A-D, and FIGS. 12A-D.

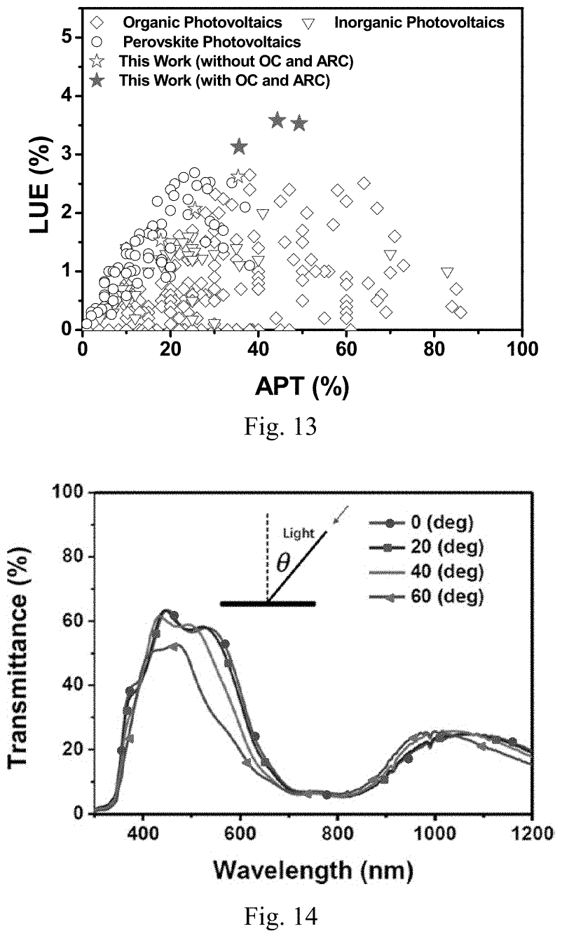

As shown in Table 1 below, compared to the opaque device, the semi-transparent device with an OC layer show a decreased J_{SC}, but similar V_{OC} and FF. The lower J_{SC} is due to the reduced reflectivity of the thin cathode, leading to the lower light absorption within the active layer. The APT and PCE of these devices vary from APT=17.8±0.5% and PCE=8.6±0.3% to APT=35.4±1.3% and PCE=7.2±0.3%, with 21 nm≥x≥11 nm. For x=11 nm, the ST-OPV shows an LUE=2.55±0.07%, and for x=16 and 21 nm, LUE=2.07±0.06% and 1.53±0.05%, respectively. These points are indicated by unfilled stars in FIG. 13.

An ARC consisting of a bilayer of 120 nm thick MgF₂ and 130 nm low refractive index SiO₂ (n_{SiO2}=1.12±0.03, obtained via glancing-angle deposition, see Methods), was deposited onto the distal surface of the glass substrate to further reduce optical reflection at the glass-air interface and increase the efficiency. The reflection ratio of the glass substrate with and without the ARC decreases by ˜4% between λ=400 nm and 1000 nm (see FIG. 8A).

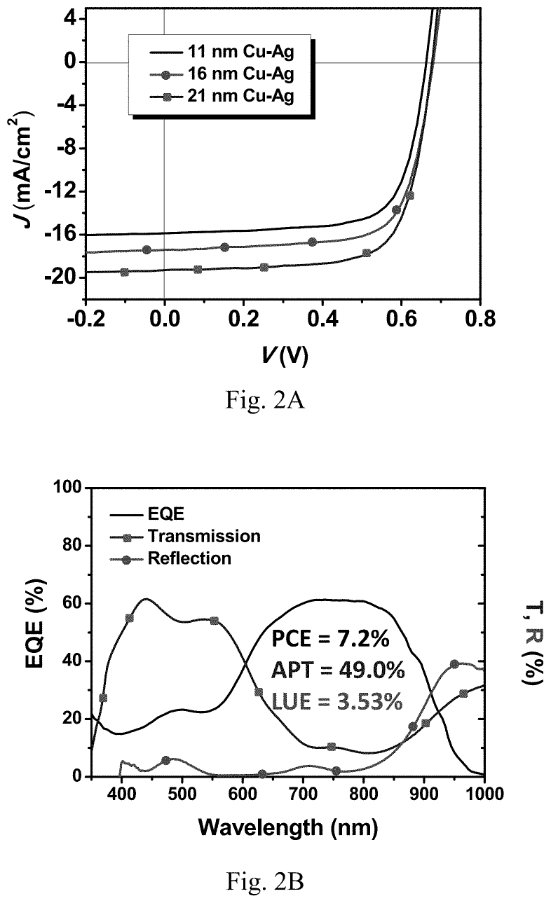

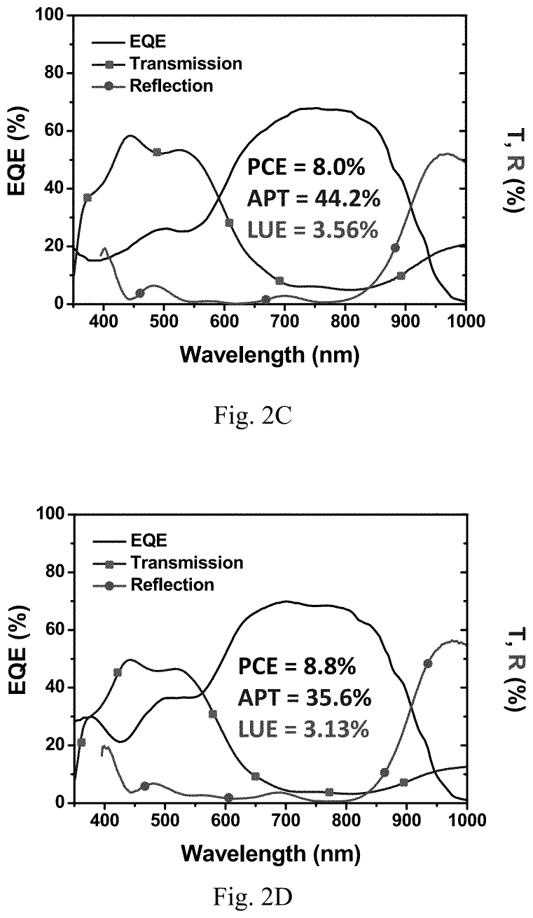

FIGS. 2A-D show the J-V and EQE characteristics of optimized ST-OPVs, together with their transmission and reflection spectra. The incorporation of OC and ARC layers significantly increases visible transmission and reduces visible reflections within all three transparent devices. It is worth noting that the PCEs maintain their initial values along with the improvement of the visible transmittance. The APT varied from 49.0±1.5% to 35.6±1.3%, with 21 nm≥x≥11 nm. For x=11 nm, the ST-OPV showed PCE=7.2±0.2% and LUE=3.53±0.10%, and for x=16 and 21 nm, PCE=8.0±0.2% and 8.8±0.3%, LUE=3.56±0.11% and 3.13±0.09%, respectively. These correspond to 38%, 72%, and 105% increases in LUE. The consistency of V_{OCs} and FFs indicate that the homogenous and continuous Cu—Ag ultra-thin films keep their morphologies during OC and ARC coating deposition. Furthermore, the higher EQE at the range of 700-1000 nm was found with the OC and ARC coatings. This increase in absorption at long wavelengths compensates the higher transmission in the visible range, resulting in the similar PCEs compared with devices lacking OC coating. In addition, optical characterization of the ST-OPVs under different angles of illumination are shown in FIG. 14. Notably, the transmittance of devices is independent of illumination angle until the angle increases to 60 degrees.

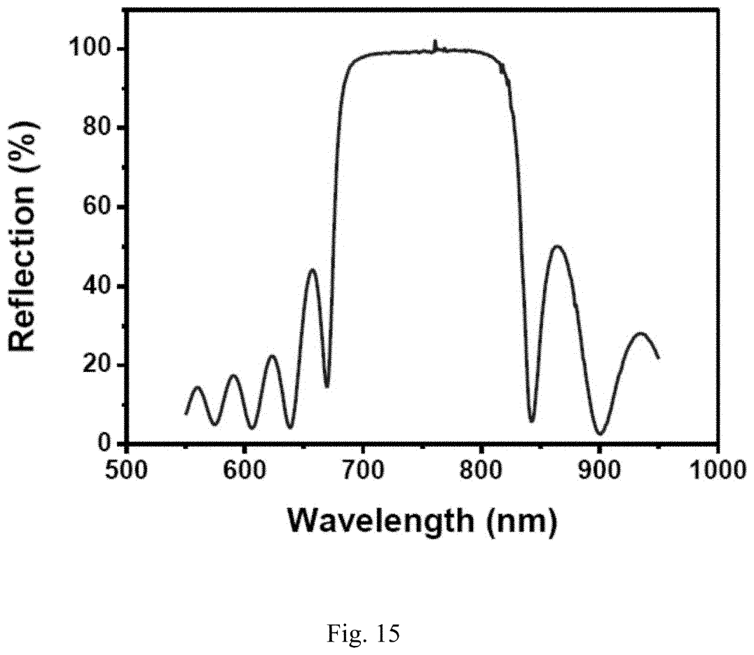

In previous work, a distributed Bragg reflector (DBR) has been used as the transparent NIR mirror to increase the NIR photon harvesting for devices with semitransparent top electrodes. The reflector was grown separately on a quartz substrate comprising 12.5 alternating layers of plasma enhanced chemical vapor deposited SiNₓ and SiO₂. As shown in FIG. 15, a similar DBR exhibited over 98% reflectance between the 650 nm and 850 nm wavelengths, which matched the absorption of the PCE-10:BT-CIC:TT-FIC (1:1.25:0.5) blend. With this NIR mirror, the ST-OPVs devices showed further increases in PCE (7.2±0.2% vs. 7.4±0.3% for 11 nm Cu—Ag device, 8.0±0.2% vs. 8.2±0.3% for 16 nm Cu—Ag device), due to higher NIR photocurrent in the active layer than achieved with the bilayer coating described herein, albeit with considerably increased complexity.

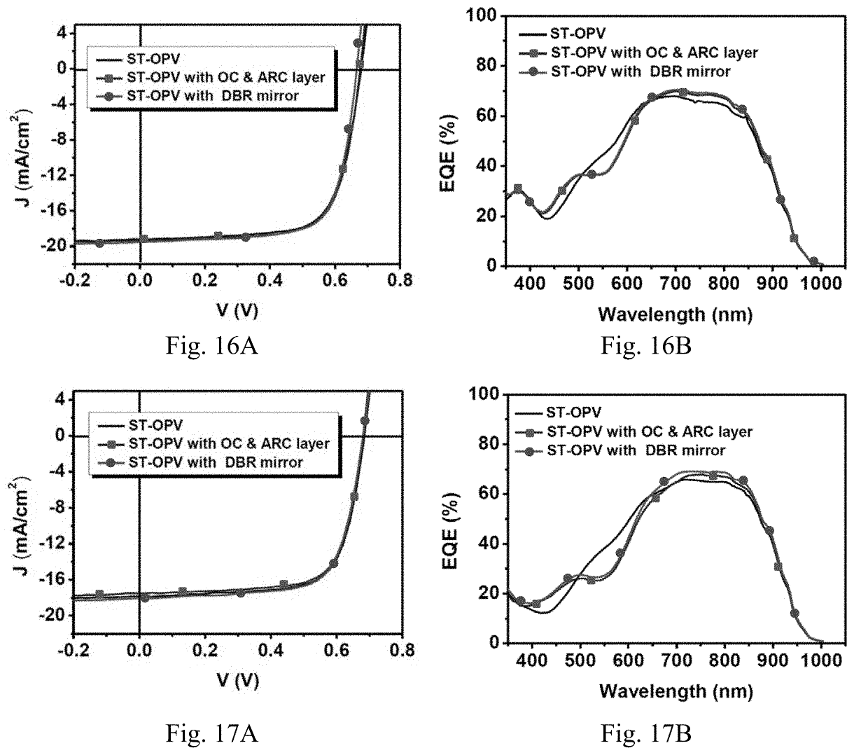

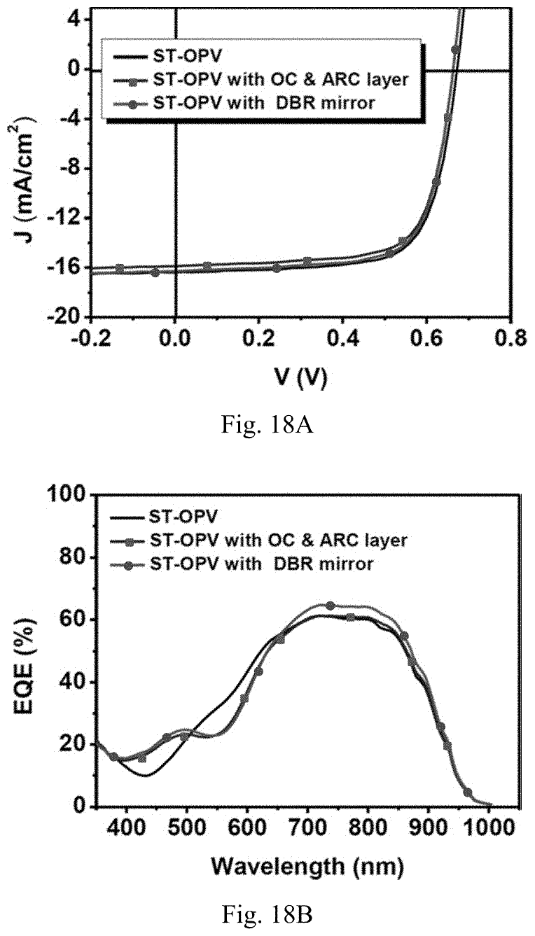

FIGS. 16A-16B, FIGS. 17A-17B, and FIGS. 18A-18B depict current-density-voltage characteristics and external quantum efficiency (EQE) spectra of semi-transparent solar cells with/without outcoupling and anti-reflection coatings (for various electrode thicknesses—21 mm CuAg, 16 mm CuAg, and 11 mm CuAg, respectively).

TABLE 1

| | J_{SC} | V_{OC} | | PCE | APT | LUE |
|---|---|---|---|---|---|---|
| Device | (mA/cm²) | (V) | FF | (%) | (%) | (%) |
| 100 nm Ag | 23.3 ± 0.4 | 0.68 ± 0.01 | 0.72 ± 0.01 | 11.4 ± 0.3 | — | — |
| 11 nm Cu—Ag | 15.0 ± 0.4 | 0.68 ± 0.01 | 0.71 ± 0.01 | 7.2 ± 0.3 | 35.4 ± 1.3 | 2.62 ± 0.07 |
| 11 nm Cu—Ag | 14.8 ± 0.3 | 0.67 ± 0.01 | 0.72 ± 0.01 | 7.2 ± 0.2 | 49.0 ± 1.5 | 3.53 ± 0.10 |
| (with OC and | | | | | | |
| ARC) | | | | | | |
| 16 nm Cu—Ag | 16.6 ± 0.3 | 0.68 ± 0.01 | 0.72 ± 0.01 | 8.1 ± 0.2 | 25.6 ± 1.0 | 2.07 ± 0.06 |
| 16 nm Cu—Ag | 16.2 ± 0.2 | 0.68 ± 0.01 | 0.72 ± 0.01 | 8.0 ± 0.2 | 44.2 ± 1.4 | 3.56 ± 0.11 |
| (with OC and | | | | | | |
| ARC) | | | | | | |
| 21 nm Cu—Ag | 17.9 ± 0.4 | 0.68 ± 0.01 | 0.71 ± 0.01 | 8.6 ± 0.3 | 17.8 ± 0.5 | 1.53 ± 0.05 |
| 21 nm Cu—A | 18.0 ± 0.4 | 0.68 ± 0.01 | 0.72 ± 0.01 | 8.8 ± 0.3 | 35.6 ± 1.3 | 3.13 ± 0.09 |
| (with OC and | | | | | | |
| ARC) | | | | | | |

Table 1 above shows operating characteristics of opaque and semi-transparent OPVs under simulated AM 1.5G, 100 mW cm⁻² illumination. The J_{SC} values listed above were calculated from the integral of the EQE spectrum. The PCE values listed above were calculated based on measurement of 8 devices. The devices measured 2 mm² and were measured under metal masks.

### Neutral- and Multi-Colored Semitransparent OPVs

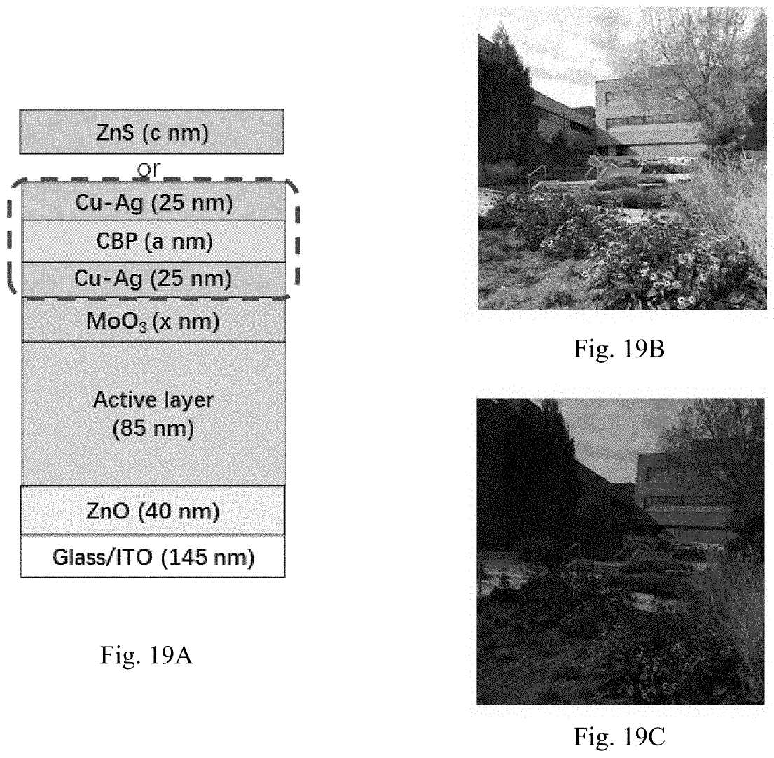

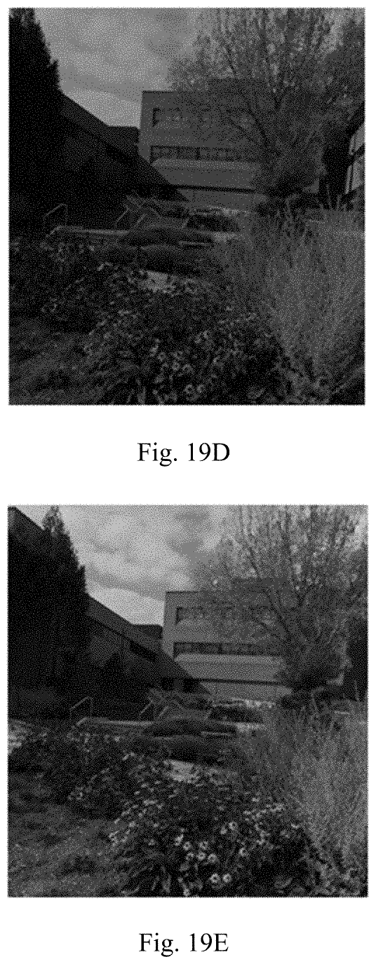

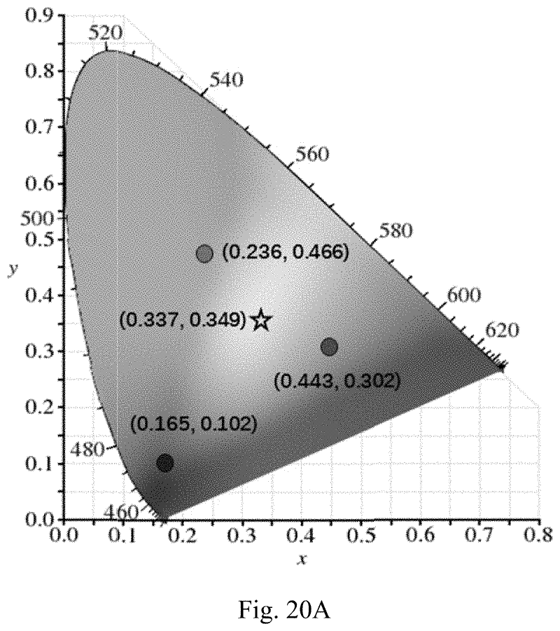

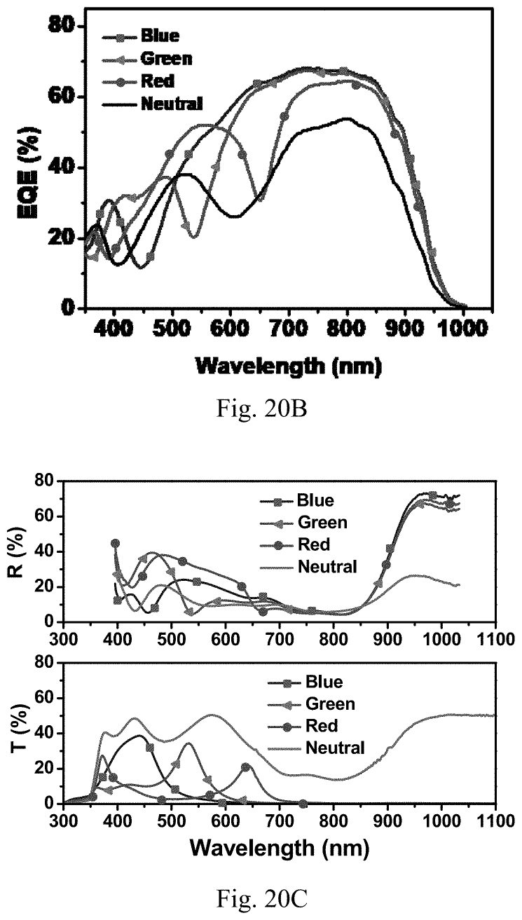

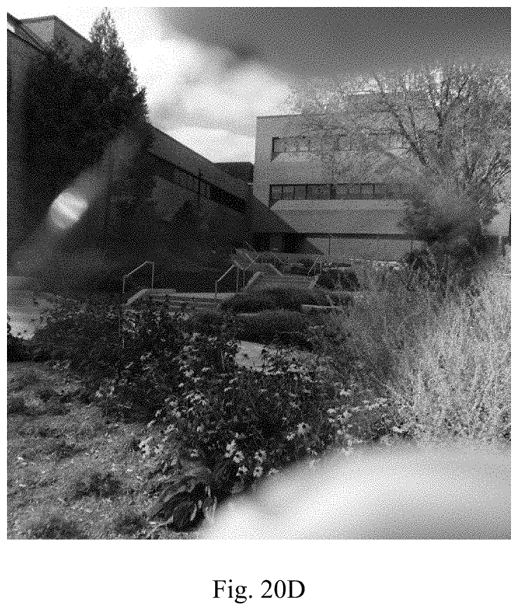

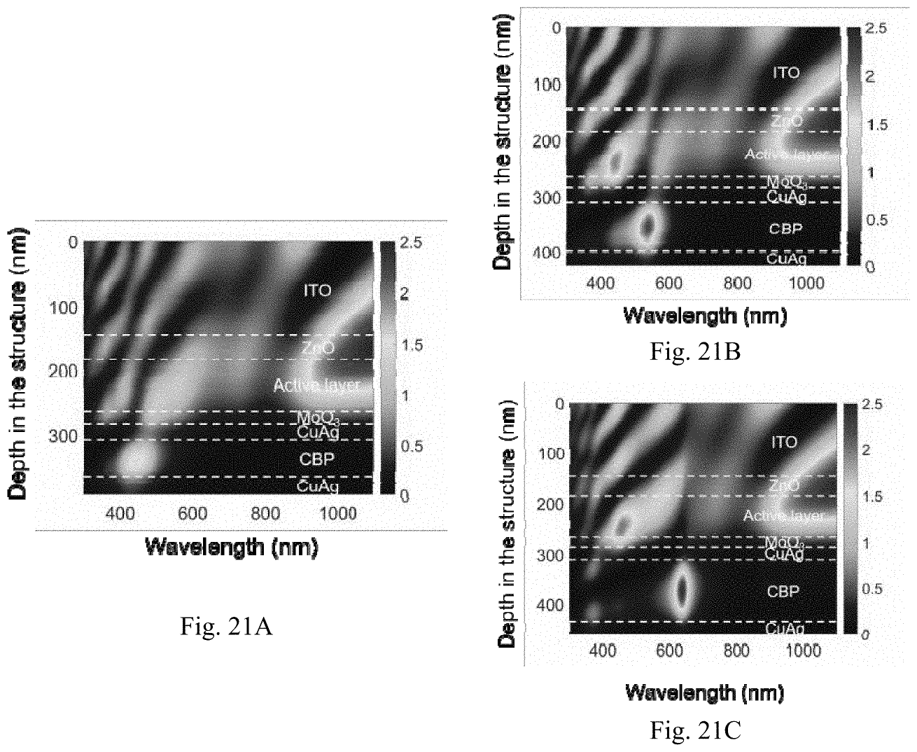

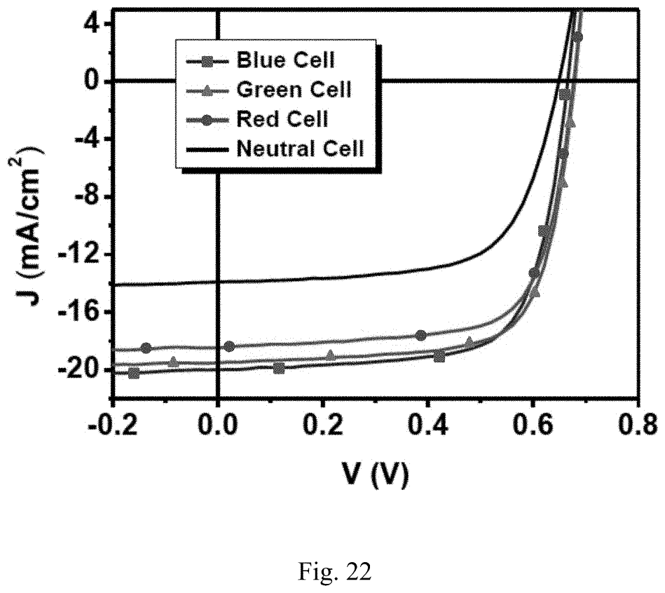

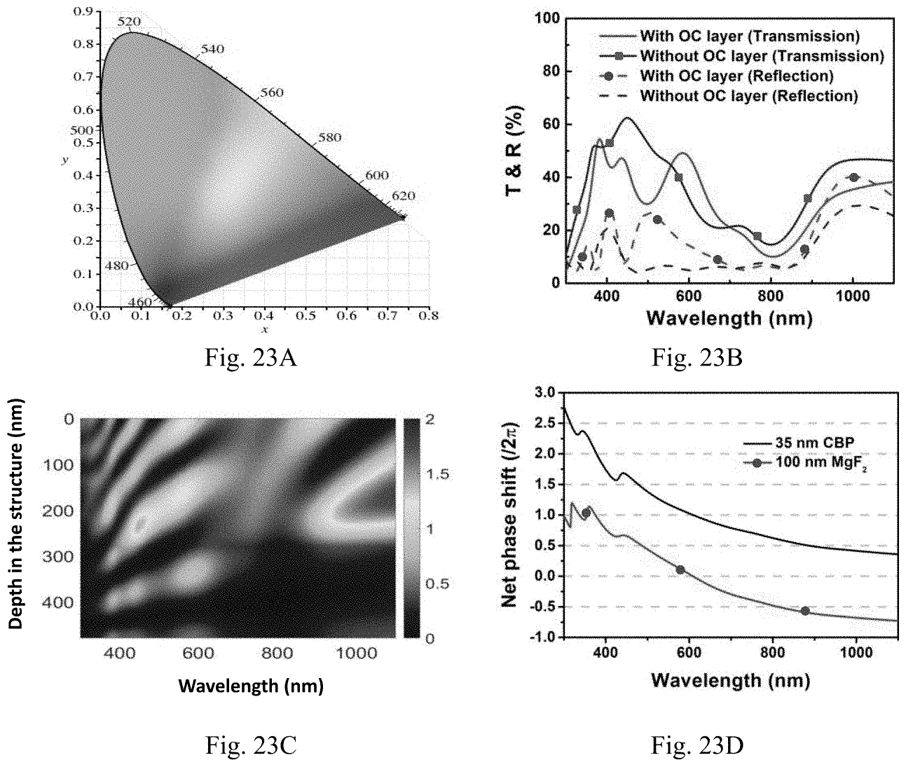

By utilizing an external optical microcavity consisting of a 25 nm Cu—Ag/CBP (x nm)/25 nm Cu—Ag coated anode, ST-OPVs transmitting a variety of hues were realized. For example, red, green, and blue (RGB) transparencies were generated with x=125 nm, x=90 nm, and x=60 nm, respectively (see FIGS. 19A-E). A pronounced transmission resonance is excited inside the Cu—Ag/CBP/Cu—Ag cavity near 635 nm, 535 nm, and 440 nm for the red, green and blue devices, respectively, which are consistent with the transmission peaks presented in FIGS. 20A-C. The peak transmittances varied from 22.0±0.7% to 39.0±1.5%. Apart from the selectively transmitted wavelengths, other wavelengths are reflected by the Cu—Ag/CBP/Cu—Ag cavity, and consequently are absorbed by the active material, which leads to a high PCE. Detailed optical analysis is depicted in FIGS. 21A-C, FIG. 22, and FIGS. 23A-D.

Operating characteristics of multi-colored semi-transparent OPVs under simulated AM 1.5G, 100 mW cm⁻² illumination are disclosed below in Table 2.

TABLE 2

| | J_{SC} | V_{OC} | | PCE |
|---|---|---|---|---|
| Device | (mA/cm²) | (V) | FF | (%) |
| Blue Color | 18.6 ± 0.5 | 0.67 ± 0.01 | 0.71 ± 0.01 | 8.9 ± 0.3 |
| Green Color | 18.1 ± 0.3 | 0.68 ± 0.01 | 0.71 ± 0.01 | 8.7 ± 0.2 |
| Red Color | 17.3 ± 0.3 | 0.68 ± 0.01 | 0.70 ± 0.01 | 8.3 ± 0.3 |
| Neutral Color | 13.2 ± 0.2 | 0.65 ± 0.01 | 0.67 ± 0.01 | 5.8 ± 0.2 |

All devices in Table 2 are 2 mm² devices measured under metal masks. The J_{SC} values listed above were calculated from the integral of the EQE spectrum. The PCE values listed above were calculated based on measurement of 8 devices.

As shown in Table 2, the blue cell has a PCE as high as 8.9±0.3%, with V_{OC}=0.67±0.01 V, J_{SC}=20.0±0.5 mA cm⁻², and FF=0.71±0.01. For the green and red devices, PCE=8.7±0.2% and 8.3±0.3% are achieved with J_{SC} (19.5±0.3 mA cm⁻² vs. 18.4±0.3 mA cm⁻²), V_{OC} (0.68±0.01 V vs. 0.68±0.01 V) and FF (0.71±0.01 vs. 0.70±0.01), respectively (FIG. 16). The variation of J_{SC} in these devices is due to the different absorption (FIG. 20B) and transmittance spectra (FIG. 20C) required to achieve the desired tint.

Finally, a color-neutral ST-OPV was demonstrated, a picture of which is shown in FIG. 20D, with the structure: (ITO)/ZnO (40 nm)/PCE-10:BT-CIC:TT-FIC (1:1.25:0.5, 85 nm)/MoO₃ (10 nm)/Cu—Ag (8 nm)/CBP (140 nm)/ZnS (56 nm). An 8 nm thick Cu—Ag layer was selected as the anode to enhance the device transparency. Due to the relatively low absorption of the PCE-10:BT-CIC:TT-FIC (1:1.25:0.5) blend in the blue and green, the ST-OPV exhibited strong transmission near 450 nm (FIGS. 23A-D) Therefore, a bilayer structure consisting of CBP and ZnS, which excites additional transmission resonances near 600 nm, was introduced to balance the blue transmission. The 1931 CIE chromaticity coordinates of the color-neutral cell were calculated by using AM1.5G simulated solar illumination are (0.337, 0.349), which is close to the isochromic (0.332, 0.343) point (FIG. 20A). This ST-OPV also exhibited a CRI=87. The neutral ST-OPV device exhibited a PCE=5.8±0.2%, with V_{OC}=0.65±0.01 V, J_{SC}=13.9±0.2 mA cm², and FF=0.67±0.01. The decreased V_{oc} and FF resulted from increased sheet resistance of the thin electrode, whereas the lower EQE is consistent with reduced J_{SC} resulting from its reduced reflectivity. Nevertheless, the APT of this cell was as high as 44.3±1.5%.

### Materials

All devices were grown on patterned indium tin oxide (ITO) substrates with sheet resistance of 15 Ω/sq. The acceptor, (4,4,10,10-tetrakis(4-hexylphenyl)-4,10-dihydrothieno [2″,3″:4′,5′] thieno[3′,2′:4,5]cyclopenta[1,2-b]thieno[2,3-d]thiophene-2,8-diyl)bis(2-(3-oxo-2,3-dihydroinden-5,6-difluoro-1-ylidene) malononitrile), TT-FIC; (4,4,10,10-tetrakis (4-hexylphenyl)-5,11-(2-ethylhexyloxy)-4,10-dihydro-dithienyl[1,2-b:4,5b]benzodi-thiophene-2,8-diyl)bis(2-(3-oxo-2,3-dihydroinden-5,6-dichloro-1-ylidene)malononitrile)) BT-CIC, were synthesized. NSM was also synthesized. Other materials were purchased from commercial suppliers: MoO₃ (Acros Organics); 4,4′-Bis(N-carbazolyl)-1,1′-biphenyl (CBP, Luminescence Technology Corp.); MgF₂ (SES Research); SiO₂ (MER Corp.); PCE-10 (1-Material); Ag (Alfa Aesar).

### Solar Cell Fabrication

Pre-patterned ITO on glass substrates were cleaned using a series of detergents and solvents, and exposed to ultraviolet-ozone for 10 mins before growth. The vacuum-deposited layers were grown at ˜1 Å/s in a high vacuum chamber with a base pressure of 2×10⁻⁷ torr. The vacuum chamber was connected to glove boxes filled with ultrapure N₂ (O₂, H₂O<0.1 ppm). A ZnO layer (approximately 40 nm) was spun cast from a ZnO precursor solution onto the substrates and then thermally annealed at 150° C. for 30 min in air. The NSM was dissolved in methanol with a concentration of 1 mg/ml and spun coated on the ZnO layer at 4000 rpm for 60 s, followed by thermal annealing at 100° C. for 10 min. Then substrate was washed by methanol at 4000 rpm for 60 s. The active layer, PCE-10:BT-CIC:TT-FIC (1:1.25:0.5 w/w/w), was dissolved in chlorobenzene:chloroform (CB:CF, 9:1 by vol.) with a concentration of 16 mg/ml. The solution was stirred overnight on a hot plate at 65° C., and then spun-coated at 2000 rpm for 90 s to achieve a thickness of ˜80 nm. The samples were then transferred back to the vacuum chamber for deposition of MoO₃.

All metal electrodes used in this work were sputtered at room-temperature with Argon (Ar) gas by a DC magnetron sputter tool (Lab18, Kurt J. Lesker Co.). The chamber base pressure was pumped down to 1×10⁻⁶ Torr for the film deposition. During the deposition, the substrate holder was rotated at a rate of 10 rpm. the Cu—Ag electrodes were deposited via co-sputtering of two pure Cu and Ag targets with the Ar gas pressure of 4.5 mTorr. The optical and electrical properties of the Cu—Ag films were optimized by adjusting the source powers for the Cu and Ag targets, which correspondingly changed the film composition. Under the optimal condition, the deposition rates of Cu and Ag were calibrated to be 0.19 Å/s and 11.09 Å/s, respectively. For the Au—Ag films, the ˜1 nm Au on the bottom was deposited at a rate of 8.3 Å/s with the Ar gas pressure of 3.5 mTorr and the top Ag was deposited at a rate of 12.4 Å/s with the Ar gas pressure of 4.5 mTorr. Pure Ag electrodes were deposited at a rate of 12.4 Å/s with the Ar gas pressure of 4.5 mTorr.

The OC coating was grown by vacuum thermal evaporation (VTE). ZnS was deposited by an electron-beam evaporator (SJ-20, Denton Vacuum, Inc.) at a rate of 3 Å/s and a pressure of 2×10⁻⁶ Torr. Finally, the ARC was grown onto the glass substrate after the devices were complete. MgF₂ was deposited by VTE at a rate of 1 Å/s and a pressure of 1×10⁻⁶ Torr, while the SiO₂ was grown by electron beam deposition with the substrate at an angle of 85° to the beam direction to achieve a low refractive index of 1.1. A distributed Bragg reflector (DBR), consisting of 12.5 pairs of 130 nm SiNₓ and 120 nm SiO₂ on fused silica substrate, was fabricated by plasma-enhanced chemical vapor deposition (Plasmatherm 790) at a rate of 5.2 Å/s for SiNₓ layer and 7.4 Å/s for SiO₂ layer.

### Solar Cell Characterization

The current density-voltage (J-V) characteristics and external quantum efficiencies (EQE) of the cells were measured in a glovebox filled with ultrapure N₂. The EQE measurements were performed with devices underfilled by a 200 Hz-chopped monochromated and focused beam from a Xe lamp. The current output from the devices as well as from a reference NIST-traceable Si detector were recorded using a lock-in amplifier. Light from a Xe lamp filtered to achieve a simulated AM 1.5G spectrum (ASTM G173-03) was used as the source for J-V measurements. The mismatch factors calculated following the reported equation are between 1.006 to 1.009. The lamp intensity controlled by neutral density filters was calibrated by a Si reference cell certified by National Renewable Energy Laboratory (NREL). Each cell was measured under six different light intensities from 0.001 sun to 1 sun (100 mW/cm²). All the solar cells in this work were measured with a mask. Errors quoted account for variations from three or more cells measured, as well as an additional systematic error of 5% for J_{SC} and PCE. Optical simulations and optimization of the single junction used MATLAB® based on the transfer matrix method in combination with the measured J-V characteristics of each cell.

### Optical and Electrochemical Characterization

The reflection spectra of fabricated devices were measured with a thin-film measurement instrument (F20, Filmetrics) integrated with a spectrometer and light source (395 nm-1032 nm). The measurements of transmission spectra and layer thicknesses were conducted with the spectroscopic ellipsometer (M-2000, J. A. Woollam Co.). The diameter of the light beam was ˜4 mm. The absorbance of solid films was measured by UV-VIS (Perkin Elmer 1050). Optical simulations based on the transfer matrix method were performed to calculate the spectral reflection and transmission, electric field intensity distributions, and the net phase shifts. The refractive indices of materials used in the simulations were calibrated using a spectroscopic ellipsometer (M-2000, J. A. Woollam Co.). The standard 4-point probe method (FPP-5000, Miller Design & Equipment) was used for the sheet resistance measurements.

The average photopic transmission (APT) is utilized in this work to evaluate the transparency of the proposed solar cells to human eyes. It takes account of the response of human eyes to light and can be calculated using the transmission spectra via

$$A P T = \frac{\int T ( λ ) P ( λ ) S ( λ ) d ( λ )}{\int P ( λ ) S ( λ ) d ( λ )} .$$

Here λ is the wavelength, T the transmission, P the normalized photopic spectral response of human eyes, and S the solar photon flux (AM1.5G).

While the present claim scope has been described with reference to specific examples, which are intended to be illustrative only and not to be limiting of the claim scope, it will be apparent to those of ordinary skill in the art that changes, additions and/or deletions may be made to the disclosed embodiments without departing from the spirit and scope of the claims.

The foregoing description is given for clearness of understanding only, and no unnecessary limitations should be understood therefrom, as modifications within the scope of the claims may be apparent to those having ordinary skill in the art.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

1. An organic photovoltaic cell, comprising:
a first electrode;
a second electrode;
an active layer comprising at least one donor material and at least one acceptor material, positioned between the first electrode and the second electrode;
an outcoupling layer positioned on a surface of the first electrode such that the first electrode is positioned between the outcoupling layer and the active layer; and
an anti-reflective coating positioned over a surface of the second electrode such that the second electrode is positioned between the anti-reflective coating and the active layer;
wherein the organic photovoltaic cell is at least semi-transparent to at least one wavelength range.

2. The organic photovoltaic cell of claim 1, wherein the outcoupling layer is configured to reflect at least a portion of light in a second wavelength range.

3. The organic photovoltaic cell of claim 2, wherein the second wavelength range comprises near-infrared light.

4. (canceled)

5. The organic photovoltaic cell of claim 1, further comprising a substrate positioned between the second electrode and the anti-reflective coating.

6. (canceled)

7. The organic photovoltaic cell of claim 1, wherein the first electrode comprises two metals.

8-9. (canceled)

10. The organic photovoltaic cell of claim 1, wherein the first electrode has a thickness of less than 15 nm.

11-12. (canceled)

13. The organic photovoltaic cell of claim 1, wherein the outcoupling layer comprises a first sublayer comprising a metal compound, and a second sublayer comprising a carbazole derivative.

14. (canceled)

15. The organic photovoltaic cell of claim 13, wherein the carbazole derivative is 4,4′-Bis(N-carbazolyl)-1,1′-biphenyl.

16. The organic photovoltaic cell of claim 1, wherein the outcoupling layer has a thickness in a range of 100-300 nm.

17. (canceled)

18. The organic photovoltaic cell of claim 1, wherein the at least one acceptor material comprises a non-fullerene acceptor.

19. (canceled)

20. The organic photovoltaic cell of claim 19, wherein the non-fullerene acceptors comprise 4,4,10,10-tetrakis(4-hexylphenyl)-5,11-(2-ethylhexyloxy)-4,10-dihydro-dithienyl[1,2-b:4,5b′]benzodi-thiophene-2,8-diyl) bis(2-(3-oxo-2,3-dihydroinden-5,6-dichloro-1-ylidene) malononitrile and 4,4,10,10-tetrakis(4-hexylphenyl)-4,10-dihydrothieno [2″,3″:4′,5′] thieno[3′,2′:4,5]cyclopenta[1,2-b]thieno[2,3-d]thiophene-2,8-diyl)bis(2-(3-oxo-2,3-dihydroinden-5,6-difluoro-1-ylidene) malononitrile; and
wherein the polymer donor comprises poly[4,8-bis(5-(2-ethylhexyl)thiophen-2-yl)benzo[1,2-b;4,5-b′]dithiophene-2,6-diyl-alt-(4-(2-ethylhexyl)-3-fluorothieno[3,4-b]thiophene-)-2-carboxylate-2-6-diyl)].

21-22. (canceled)

23. The organic photovoltaic cell of claim 22, further comprising an interfacial layer positioned between the buffer layer and the active layer.

24. The organic photovoltaic cell of claim 23, wherein the buffer layer comprises ZnO and the interfacial layer comprises a non-fullerene surfactant material.

25. An organic photovoltaic cell comprising:
an active layer comprising at least one donor material and at least one acceptor material;
an electrode positioned over the active layer, comprising at least one metal material; and
an outcoupling layer positioned over the electrode, the outcoupling layer configured to reflect at least a portion of near-infrared light;
wherein the organic photovoltaic cell is configured to be at least semi-transparent to at least one wavelength range.

26. (canceled)

27. The organic photovoltaic cell of claim 25, further comprising a distributed Bragg reflector positioned over the outcoupling layer.

28. The organic photovoltaic cell of claim 25, wherein the organic photovoltaic cell has an average transmittance in the visible range of at least 60%.

29. (canceled)

30. The organic photovoltaic cell of claim 25, wherein the organic photovoltaic cell has a light utilization efficiency of at least 3%.

31. (canceled)

32. A method of fabricating an organic device, comprising:
positioning a first electrode on a substrate;
positioning an active layer over the first electrode;
depositing a second electrode over the active layer, the second electrode being a thin film having a first metal deposited at a first deposition rate and a second metal different from the first metal deposited at a second deposition rate different from the first deposition rate; and
positioning an outcoupling layer over the second electrode.

33. The method of claim 32, wherein the first and second metals are selected from the group consisting of Ag, Au, Pd, Pt, Ti, V, Zn, Sn, Al, Co, Ni, Cu, and Cr.

34. The method of claim 32, wherein the first deposition rate is at least 50 times the second deposition rate.

35-38. (canceled)
